(19) United States
(12) Patent Application Publication
(10) Pub. No.: US 2022/0056592 A1
(43) Pub. Date: Feb. 24, 2022

(54) SINGLE RUN DEPOSITION FOR FORMING SUPERCOMPOSITE STRUCTURES

(71) Applicants: UNIVERSITY OF SURREY, Guildford, Surrey (GB); AIRBUS DEFENCE AND SPACE GMBH, Taufkirchen (DE)

(72) Inventors: José Virgilio Anguita RODRIGUEZ, Guildford, Surrey (GB); Sembukuttiarachilage Ravi Pradip SILVA, Guildford, Surrey (GB); Christopher Toby Gibb SMITH, Guildford, Surrey (GB); Michal DELKOWSKI, Guildford, Surrey (GB)

(73) Assignees: UNIVERSITY OF SURREY, Guildford, Surrey (GB); AIRBUS DEFENCE AND SPACE GMBH, Taufkirchen (DE)

(21) Appl. No.: 17/414,050

(22) PCT Filed: Dec. 18, 2019
(86) PCT No.: PCT/GB2019/053604

§ 371 Date: Jun. 15, 2021

(30) Foreign Application Priority Data
Dec. 18, 2018 (GB) 1820625.0

(51) Int. Cl. C23C 28/00; C23C 16/26; B05D 1/00; C23C 16/06

(52) U.S. Cl. CPC C23C 28/343; C23C 16/06; B05D 1/62; C23C 16/26

(57) ABSTRACT

A method for depositing a multilayer coating onto a substrate includes supporting the substrate on a platen comprising an electrically conductive material disposed in a deposition chamber, connected to an electrical power supply and electrically insulated from an electrode. The pressure in the deposition chamber is less than 10 Torr when a first feedstock is fed to the substrate. The electrical power supply is activated to create a plasma surrounding the substrate which ionises and/or activates particles within the first feedstock, allowing the ionised and/or activated particles from the first feedstock to deposit on the substrate and polymerise, thereby forming a first a coating on the substrate. Particles of a second feedstock, different from the first feedstock, are fed to the substrate and are ionized and/or activated by the plasma and allowed to deposit on the substrate and polymerise to form a second coating on the substrate. The pressure in the deposition chamber does not rise above 700 Torr between feedstocks fed therein.

### CROSS-REFERENCE TO RELATED APPLICATIONS

This application is a United States National Stage Application of International Application No. PCT/GB2019/053604 filed Dec. 18, 2019, claiming priority from Great Britain Patent Application No. 1820625.0 filed Dec. 18, 2018.

### FIELD OF THE INVENTION

The present invention relates to an apparatus for applying a multilayer film to a component. The invention extends to a method of applying the multilayer film to the substrate and to coated substrates produced using the method.

Polymers and composites, in particular carbon fibre reinforced plastics (CFRP), which are used in advanced engineering applications are subjected to many environmental threats. Compared to other market areas, aerospace is particularly challenging because of the harsh operational environment and rigorous requirements for both structural and non-structural components.

### BACKGROUND

For the particular case of aerospace applications, environmental threats to the polymers may include humidity, secondary vacuum, charged particle (ionizing) radiation, solar ultraviolet (UV) radiation, atomic oxygen (ATOX), plasma, surface charging and arcing, thermal cycling, temperature extremes, mechanical and thermal environment on ground and in the flight, impacts from micrometeoroids and orbital debris (MMOD), environment induced contamination, corrosion induced effects, de-icing and so forth. It may be appreciated that the threat to a specific component may vary depending upon the material's nature, the specific orbital parameters for the mission, the mission duration, solar events and the solar cycle during the mission, the view angle of the spacecraft's surfaces to the sun as well as the orientation of the spacecraft's surfaces towards the spacecraft's velocity vector in particular low Earth orbits.

The addition of one or more layers to the CFRP has been investigated. The layers can be configured to provide a moisture and outgassing barrier, thereby preventing dimensional instability as well as contamination of sensitive surfaces or optical instruments which may be supported by the composites. If suitable layers are not provided, the outgassing of volatile contaminates may significantly diminish an optical instrument's throughput. Alternatively, or additionally, the layers could functionalise the composite to offer improved electrical, thermal conducting and/or thermo-optical properties.

However, the CFRP can have a highly dynamic surface, making it difficult to apply layers thereto. This is because both, the fibres and the polymer matrix may have very strong physical and mechanical properties, which are in opposition to each other. For example, carbon fibres have ˜zero coefficient of thermal expansion (CTE), and sometimes a negative CTE, whereas a polymer matrix may have a high CTE values, e.g. ˜60 parts per million (ppm). This severe mismatch of CTE's between the fibres and the polymer may cause the composite material to have a highly dynamic surface. In addition, since the fibres are aligned along substantially one single direction for each layer, the surface of the CFRP generally has anisotropic mechanical properties. Accordingly, additional layers may be required to act as a buffer and accommodate the mechanical motions of the surface of the composite.

The inventors have found that there is often low adhesion between the layers provided on the CFRP. This can lead to mechanical failure of components comprising the CFRP.

### SUMMARY

The present invention arises from the inventors work in trying to overcome the problems associated with the prior art.

In accordance with a first aspect of the invention, there is provided a method for depositing a multilayer coating onto a substrate, the method comprising:
supporting the substrate on a platen comprising an electrically conductive material, wherein the platen is disposed in a deposition chamber, is connected to an electrical power supply and is electrically insulated from an electrode;
reducing the pressure in the deposition chamber to less than 10 Torr;
feeding a first feedstock to the substrate;
activating the electrical power supply and thereby creating a plasma that surrounds the substrate and ionises and/or activates particles within the first feedstock;
allowing the ionised and/or activated particles from the first feedstock to deposit on the substrate and polymerise, and thereby form a first layer of a coating on the substrate;
feeding a second feedstock to the substrate such that the plasma ionises and/or activates particles within the second feedstock, wherein the second feedstock is different to the first feedstock; and
allowing the ionised and/or activated particles from the second feedstock to deposit on the substrate and polymerise, and thereby form a second layer of the coating on the substrate;
   characterised in that the pressure in the deposition chamber does not rise above 700 Torr between feedstocks being fed into the deposition chamber.

Advantageously, the method of the first aspect provides a multilayer coating on a substrate at room temperature without shadowing effects and/or vacuum interruption. It may be appreciated that the term “shadowing” refers to a line of sight effect whereby, using prior art processes, coating regions are blocked by obstructions upstream. This effect is not observed using the above method, as the direction of deposition is dictated primarily by the plasma, rather than the flow of reactants. Accordingly, the method allows non-line-of-sight coatings to be produced. Furthermore, the coating obtained using the above method may be fully conformal. The inventors have found that even for surfaces with highly complex three-dimensional geometries the coating may be defect-free and pinhole-free. As shown in the Examples, after deposition the coating forms an integral part of the composite, so that the “coated substrate” becomes one composite. Accordingly, the composite is devoid of stress. Furthermore, the coating can be applied to any substrate to provide protection or enhanced properties.

The pressure in the deposition chamber may not rise above 600 Torr, above 500 Torr or above 400 Torr between feedstocks being fed into the deposition chamber, preferably the pressure in the deposition chamber does not rise above 300 Torr, above 200 Torr or above 100 Torr between feedstocks being fed into the deposition chamber, more preferably the pressure in the deposition chamber does not rise above 80 Torr or above 60 Torr between feedstocks being fed into the deposition chamber, and most preferably the in the deposition chamber pressure does not rise above 40 Torr or 20 Torr between feedstocks being fed into the deposition chamber.

Preferably, the pressure in the deposition chamber does not rise above 700 Torr, above 600 Torr, above 500 Torr, above 400 Torr, above 300 Torr, above 200 Torr or above 100 Torr while a feedstock is being fed into the deposition chamber, more preferably the pressure in the deposition chamber does not rise above 80 Torr or above 60 Torr while a feedstock is being fed into the deposition chamber, and most preferably the pressure in the deposition chamber does not rise above 40 Torr or 20 Torr while a feedstock is being fed into the deposition chamber.

Accordingly, the pressure in the deposition chamber preferably does not rise above 700 Torr, above 600 Torr, above 500 Torr, above 400 Torr, above 300 Torr, above 200 Torr or above 100 Torr from when it is reduced until after a final coating layer has been formed on the substrate, more preferably the pressure in the deposition chamber does not rise above 80 Torr or above 60 Torr from when it is reduced until after a final coating layer has been formed on the substrate, and most preferably the pressure in the deposition chamber does not rise above 40 Torr or 20 Torr from when it is reduced until after a final coating layer has been formed on the substrate.

The platen may comprise a metal or a conductive composite material. The conductive composite material may comprise a carbon fibre reinforced polymer (CFRP).

The deposition chamber and/or the platen may be maintained at a temperature between −20° C. and 180° C., more preferably between ° C. and 100° C. or between 1° C. and 50° C., and most preferably between 15° C. and 30° C. Accordingly, the method may comprise controlling the temperature within the deposition chamber and/or the temperature of the platen. Advantageously, the inventors have found that their method can be conducted at room temperature. Alternatively, depending on the needs and material formulation the temperature could be modified to outside this range. For instance, it may be possible to modify the structure of the coating by using a higher temperature. Accordingly, if this is desired, the temperature may be between 100° C. and 500° C.

The substrate may comprise an electrically insulating material. The substrate may consist of an electrically insulating material. The substrate may comprise a substantially flat surface. The substrate may have a thickness of less than 25 cm, more preferably less than 10 cm, less than 7.5 cm or less than 5 cm, and most preferably less than 3 cm, less than 2 cm or less than 1 cm. The substrate may comprise a plastic, a glass, an optically transparent material, a paper, a ceramic and/or an elastomer. The substrate may comprise a multi-layer insulation (MLI) material. The optically transparent material may be a material used for manufacturing lenses for use in the visible, ultraviolet and infrared spectrum, such as germanium (Ge), potassium bromide (KBr) and/or sodium chloride (NaCl). Alternatively, or additionally, the substrate may comprise a glass-fibre reinforced plastic (GFRP).

In embodiments where the substrate comprises an electrically insulating material, the platen preferably comprises a plate configured to receive the substrate thereon. Preferably, the plate is substantially flat. Advantageously, the electric field that the platen generates is able to penetrate through the insulating substrate thereby creating a plasma as described above. The plasma is driven by the platen and, since the substrate is disposed between the platen and the plasma, the coating layers deposit thereon.

However, in a preferred embodiment, the substrate comprises an electrically conductive material.

In some embodiments, the substrate may comprise an electrically insulating material and an electrically conductive material. The electrically conducting material may comprise a mesh disposed within or around the electrically insulating material. Alternatively, the electrically conductive material may define a layer disposed on an outer surface of the electrically insulating material.

Alternatively, the substrate may consist of an electrically conducting material.

Advantageously, the method of the first aspect can deposit a coating onto an electrically conductive substrate with a complex three dimensional shape. The ionised monomers are attracted to the charged substrate, deposit thereon and polymerise, creating an even layer of coating, even on complex surfaces. It may be appreciated that any electrically conducting substrate could be coated using the method of the first aspect. Accordingly, the substrate could comprise a metal, graphite, graphene, carbon nanotubes and/or a conductive composite material. In a preferred embodiment, the substrate is a carbon fibre reinforced polymer (CFRP).

In embodiments where the substrate comprises an electrically conductive material, the platen may comprise a plate configured to receive the substrate thereon. The plate may be as defined above. However, in a preferred embodiment, the platen comprises a resilient clip configured to receive a portion of the electrically conductive substrate. The resilient clip may comprise a pair of corresponding flanges configured to receive the portion of the electrically conductive substrate therebetween. Preferably, the portion of the electrically conductive substrate comprises less than 10% of the surface area of the substrate, more preferably less than 5%, less than 4% or less than 3% of the surface area of the substrate, and most preferably less than 2% or less than 1% of the surface area of the substrate.

In some embodiments, the electrode may be disposed in the deposition chamber. However, in a preferred embodiment, the deposition chamber defines the electrode. Accordingly, the deposition chamber may comprise a conductive material. The conductive material may comprise a metal or a conductive composite material, such as a carbon fibre reinforced polymer (CFRP).

The electrode may be connected to a power supply. However, in a preferred embodiment, the electrode is connected to electrical ground or earth. Accordingly, the electrode may be an earthed electrode. In embodiments where the deposition chamber defines the electrode, the apparatus may comprise an earthed conductive housing.

A further layer may be formed by:
feeding a further feedstock to the substrate such that the plasma ionises and/or activates particles within the further feedstock; and
allowing the ionised and/or activated particles from the further feedstock to deposit on the substrate and polymerise, and thereby form a further layer of the coating on the substrate.

The further feedstock may be different to the first and/or second feedstock. The method may comprise forming multiple further layers.

Each feedstock may comprise:
a feedstock configured to provide a poly(p-xylylene) layer;
a feedstock configured to provide a diamond-like carbon (DLC) layer;
a feedstock configured to provide a layer comprising a metal or metalloid; or
a feedstock configured to provide an inorganic layer.

A metalloid may be understood to be a chemical element with properties that are intermediate between those of metals and nonmetals. For instance, the metalloid may be boron, silicon, germanium, arsenic, antimony, tellurium and polonium, and is preferably silicon.

It may be appreciated that the poly(p-xylylene) layer, DLC layer, layer comprising a metal or metalloid and/or inorganic layer produced using the method could be pure layers consisting entirely of poly(p-xylylene), DLC, a metal or metalloid and/or the inorganic component. Alternatively, it may be appreciated that the layers may be doped layers. Accordingly, the layers could comprise one or more dopants. Suitable dopants are defined below.

The feedstock configured to provide a poly(p-xylylene) layer may comprise a poly(p-xylylene) monomer. The poly(p-xylylene) monomer may be configured to provide a polymer of formula (I):

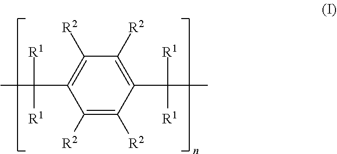

wherein each R¹ is independently H or a polymer group chain or a halogen; and each R² is independently H, a C₁₋₅ alkyl or a halogen.

The halogen may be fluorine, chlorine, bromine or iodine, and is preferably fluorine or chlorine. In a preferred embodiment, each R¹ is independently H or fluorine; and each R² is independently H or fluorine.

Accordingly, the monomer may be configured to produce a poly(p-xylylene) of formula (Ia), (Ib), (Ic) or (Id):

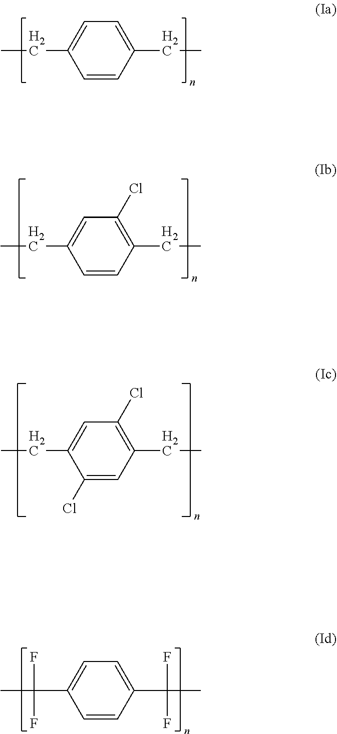

The feedstock configured to provide a DLC layer may comprise a carbon source. The carbon source may comprise a C₁ to C₁₅ alkyl, a C₃ to C₁₀ cycloalkyl and/or a C₆ to C₁₀ aryl, wherein the alkyl, cycloalkyl and/or aryl are optionally substituted with a halogen and/or the cycloalkyl and/or aryl are optionally substituted with one or more C₁ to C₁₅ alkyl groups. Preferably, the carbon source comprises a C₁ to C₁₀ alkyl, a C₆ cycloalkyl and/or a C₆ aryl, wherein the alkyl, cycloalkyl and/or aryl are optionally substituted with a halogen and/or the cycloalkyl and/or aryl are optionally substituted with one or more C₁ to C₅ alkyl groups. The halogen is preferably fluorine. Advantageously, the feedstock may produce fluorine doped DLC. The alkyl may be a straight or branched chain alkyl. Accordingly, the carbon source may comprise n-hexane, cyclohexane and/or toluene. Alternatively, the carbon source may comprise a hydrocarbon gas. The hydrocarbon gas may comprise a C₁ to C₅ hydrocarbon. The hydrocarbon gas may comprise methane, ethane, propane, butane, pentane and/or acetylene. The feedstock may comprise the carbon source in an amount which is between 0.01 and 100% (v/v), more preferably between 0.1 and 75% (v/v) or between 1 and 50% (v/v) and most preferably between 5 and 40% (v/v).

The feedstock configured to provide a DLC layer may further comprise a further gas. The further gas may be a noble gas, nitrogen gas and/or hydrogen gas. The noble gas may comprise helium or argon. The feedstock may comprise the further gas at a concentration between 0 and 99.99% (v/v), more preferably between 25 and 99.9% (v/v) or between 50 and 99% (v/v) and most preferably between 60 and 95% (v/v).

The feedstock configured to provide a DLC layer may further comprise one or more dopants.

The dopant may comprise a metal, preferably a transition metal. Accordingly, the feedstock may comprise a metal, preferably a transition metal. In some embodiments, the feedstock may comprise an organometallic. Advantageously, the organometallic may act as a metal source. The transition metal may be titanium, iron, nickel, cobalt or molybdenum. Advantageously, the metal reduces friction and enhances electrical conductivity. The feedstock may comprise the metal and/or the organometallic at a concentration between 0 and 99.99% (v/v), more preferably between 0.1 and 50% (v/v) or between 0.5 and 25% (v/v) and most preferably between 1 and 5% (v/v).

The dopant may comprise an oxide and/or a nitride, such as silicon oxide (SiOₓ), titanium oxide (TiOₓ) and/or silicon nitride (Si₃N₄). Accordingly, the feedstock may comprise silicon oxide (SiOₓ), titanium oxide (TiOₓ) and/or silicon nitride (Si₃N₄). Advantageously, an oxide or nitride increases heat resistance, minimize friction and increase transparency, scratch resistance and ATOX and/or UV protection. The feedstock may comprise the oxide and/or the nitride at a concentration between 0 and 99.99% (v/v), more preferably between 0.1 and 50% (v/v) or between 0.5 and 25% (v/v) and most preferably between 1 and 5% (v/v).

The dopant may comprise a halogen, oxygen, nitrogen, boron, and/or silicon. Accordingly, the feedstock may comprise a halogen, oxygen, nitrogen, boron, and/or silicon. The feedstock may comprise the halogen, oxygen, nitrogen, boron, and/or silicon at a concentration between 0 and 99.99% (v/v), more preferably between 0.1 and 50% (v/v) or between 0.5 and 25% (v/v) and most preferably between 1 and 5% (v/v).

The feedstock configured to provide a metal or metalloid layer may comprise a metal or metalloid source. The metal source may comprise an organometallic compound. The metal source may be a source of a transition metal or a group 13 metal. The metal source may be a source of tungsten (W), titanium (Ti), niobium (Nb), tantalum (Ta), nickel (Ni), molybdenum (Mo) or aluminium (Al). The metalloid source may comprise boron, silicon, germanium, arsenic, antimony, tellurium or polonium, and preferably comprises silicon.

The feedstock configured to provide the inorganic layer may be conjured to provide a carbide, oxide or nitride. Accordingly, the feedstock configured to provide the inorganic layer may comprise a carbon, oxygen and/or nitrogen source. The feedstock configured to provide the inorganic layer may be conjured to provide a layer comprising a transition metal or p-block metal or metalloid. Accordingly, the feedstock configured to provide the inorganic layer may comprise a transition metal or p-block metal or metalloid source. The transition metal or p-block metal or metalloid may be selected from the group consisting of tungsten (W), titanium (Ti), niobium (Nb), tantalum (Ta), nickel (Ni), molybdenum (Mo), aluminium (Al) or silicon (Si). The feedstock may be configured to provide a layer comprising silicon carbide (SiCₓ), silicon oxide (SiOₓ), silicon oxynitride (SiOₓN_{y}), titanium oxynitride (TiNₓO_{y}), titanium nitride (TiNₓ), titanium oxide (TiOₓ), silicon nitride (SiₓN_{y}) or aluminium oxide (AlₓO_{y}). It may be appreciated that suitable feedstocks will be known by the skilled person. For instance, a feedstock configured to produce a silicon oxide layer may comprise silane (SiH₄) and oxygen.

The method may comprise forming at least two, three, four, five, six, seven or eight layers of the coating on the substrate. It may be appreciated that there is no limit to the number of layers that may be applied. The number of layers will depend upon the substrate material, the roughness of the surface of the substrate and desired properties of the coated substrate.

In embodiments where the platen comprises a plate it may be appreciated that the layer of the coating may only deposit on one side of the substrate. Accordingly, the method may cause a multilayer coating to deposit on a first side of the substrate. The method may then comprise repositioning the substrate on the platen to expose a second, uncoated side thereof. The substrate may be repositioned manually or automatically. It may be appreciated that if the substrate is repositioned manually then it may be necessary to break the vacuum in the deposition chamber. Accordingly, the pressure in the deposition chamber may rise above 700 Torr while the substrate is being repositioned.

Alternatively, if the substrate is positioned automatically, it may not be necessary to break the vacuum in the deposition chamber. Accordingly, in this embodiment, the pressure in the deposition chamber may not rise above 700 Torr while the substrate is being repositioned. The pressure in the deposition chamber may not rise above 600 Torr, above 500 Torr or above 400 Torr while the substrate is being repositioned, preferably the pressure in the deposition chamber does not rise above 300 Torr, above 200 Torr or above 100 Torr while the substrate is being repositioned, more preferably the pressure in the deposition chamber does not rise above 80 Torr or above 60 Torr while the substrate is being repositioned, and most preferably the in the deposition chamber pressure does not rise above 40 Torr or 20 Torr while the substrate is being repositioned.

Once the substrate has been repositioned, the method may then be repeated to deposit the multi-layered coating on the second side of the substrate. Again, the pressure in the deposition chamber may not rise above 700 Torr between feedstocks being fed into the deposition chamber during the repeated method.

Alternatively, the method may comprise forming each layer on both sides of the substrate prior to depositing a subsequent layer. Accordingly, when the first layer of the coating has reached a desired thickness, the method may further comprise:
repositioning the substrate on the platen to expose a second, uncoated side thereof;
feeding the first feedstock to the substrate such that the plasma ionises and/or activates particles within the second feedstock; and
allowing the ionised and/or activated particles from the first feedstock to deposit on the second side of the substrate and polymerise, and thereby form a first layer of a coating on the second side of the substrate.

The substrate may be repositioned automatically, without breaking the vacuum in the deposition chamber. Accordingly, the pressure in the deposition chamber may not rise above 700 Torr while the substrate is being repositioned. The pressure in the deposition chamber may not rise above 600 Torr, above 500 Torr or above 400 Torr while the substrate is being repositioned, preferably the pressure in the deposition chamber does not rise above 300 Torr, above 200 Torr or above 100 Torr while the substrate is being repositioned, more preferably the pressure in the deposition chamber does not rise above 80 Torr or above 60 Torr while the substrate is being repositioned, and most preferably the in the deposition chamber pressure does not rise above 40 Torr or 20 Torr while the substrate is being repositioned.

The method may comprise stopping feeding the first feedstock to the substrate when the first layer of the coating has reached a desired thickness on both sides of the substrate. The method may then comprise feeding the second feedstock to the substrate.

The method may initially form the second layer of the coating on the second side of the substrate. Accordingly, when the second layer of the coating has reached a desired thickness, the method may further comprise:
repositioning the substrate on platen to expose the first side thereof;
feeding the second feedstock to the substrate such that the plasma ionises and/or activates particles within the second feedstock; and
allowing the ionised and/or activated particles from the second feedstock to deposit on the first side of the substrate and polymerise, and thereby form a second layer of a coating on the first side of the substrate.

The method may comprise stopping feeding the second feedstock to the substrate when the first layer of the coating has reached a desired thickness on both sides of the substrate. The method may then comprise feeding subsequent feedstocks to the substrate.

It may be appreciated that the method may comprise corresponding steps to reposition the substrate during deposition of any subsequent layers.

Feeding a feedstock to the substrate may comprise feeding the feedstock into the deposition chamber.

The method may comprise feeding the first feedstock into the deposition chamber when the pressure therein falls below a predetermined pressure. The predetermined pressure may be less than 10 Torr, less than 1 mTorr or less than 0.1 mTorr, more preferably less than 50 mTorr, less than 40 mTorr, less than 30 mTorr, less than 20 mTorr or less than 10 mTorr, and most preferably less than 5 mTorr or less than 1 mTorr.

Feeding the first feedstock into the deposition chamber may cause the pressure in the deposition chamber to rise. The method may comprise monitoring the pressure in the deposition chamber while feeding the first feedstock therein, and activating the electrical power supply after the pressure reaches a predetermined pressure. The predetermined pressure may be a pressure of at least 1 mTorr, more preferably at least 10 mTorr, at least 20 mTorr, at least 30 mTorr, at least 40 mTorr or at least 50 mTorr, and most preferably at least 0.1 Torr, at least 1 Torr or at least 10 Torr.

The method may comprise monitoring the thickness of the coating. The method may comprise stopping feeding a feedstock to the substrate when a layer of the coating has reached a desired thickness. Alternatively, the method may comprise stopping feeding a feedstock to the substrate after the feedstock has been fed into the deposition chamber for a predetermined time.

After a feedstock has stopped being fed into the deposition chamber, the method may comprise feeding a further feedstock to the substrate. For instance, the method may comprise monitoring the thickness of the first layer, and stopping feeding the first feedstock to the substrate when the first layer of the coating has reached a desired thickness. The method may then comprise feeding the second feedstock to the substrate.

Before depositing a further layer on the substrate, the method may comprise reducing the pressure in the deposition chamber. Reducing the pressure may comprise reducing the pressure to a predetermined pressure. The predetermined pressure may be as defined above. The method may comprise feeding the second feedstock, or a subsequent feedstock, into the deposition chamber when the pressure falls below the predetermined pressure.

After a desired thickness of the layer of coating has been formed on the substrate, the method may comprise deactivating the electrical power supply. The method may then comprise monitoring the pressure in the deposition chamber while feeding a subsequent feedstock therein, and activating the electrical power supply after the pressure reaches a predetermined pressure. The predetermined pressure may be as defined above.

However, in a preferred embodiment, the method does not comprise deactivating the power supply between feeding subsequent feedstocks into the deposition chamber.

The method may comprise changing the power parameters for different feedstocks.

The electrical power supply is preferably a direct current (DC) power supply or a radio-frequency electrical power supply, and more preferably is a radio-frequency electrical power supply. Preferably, the radio-frequency electrical power supply operates at a frequency between 0.1 and 100 MHz, more preferably between 1 and 50 MHz or between 5 and 25 MHz, and most preferably at a frequency between 7.5 and 20 MHz or between 10 and 15 MHz. In a preferred embodiment, the radio-frequency electrical power supply operates at a frequency of 13.56 MHz as this is an industrial, scientific and medical (ISM) radio band.

Activating the electrical power supply may comprise applying an electrical power to the electrically conductive substrate and/or the platen of between 0.0001 Watts/cm² and 10 Watt/cm², more preferably between 0.001 Watts/cm² and 5 Watt/cm² or between 0.005 Watts/cm² and 1 Watts/cm² and most preferably between 0.01 and 0.5 Watts/cm².

After the desired number of layers have been deposited on the substrate, the method may comprise venting the deposition chamber. The method may comprise deactivating the electrical power supply prior to venting the deposition chamber. Venting the deposition chamber may comprise raising the pressure therein to atmospheric pressure.

In some embodiments, the first feedstock is configured to provide a poly(p-xylylene) layer. The inventors have found that a layer of poly(p-xylylene) can accommodate the mechanical motions of the surfaces of anisotropic materials such as composites, in particular CFRP.

Prior to feeding the feedstock configured to provide a poly(p-xylylene) layer into the deposition chamber, the method may comprise decomposing a poly(p-xylylene) dimer to obtain a poly(p-xylylene) monomer, and then feeding the poly(p-xylylene) monomer into the deposition chamber. The method may comprise heating the poly(p-xylylene) dimer to a temperature of at least 200° C., more preferably at least 300°, at least 400° C. or at least 500° C., and most preferably at least 600° C. or at least 650° C. to cause the poly(p-xylylene) dimer to decompose. The method may comprise heating the poly(p-xylylene) dimer to a temperature between 200° C. and 1500° C., more preferably between 300° C. and 1400° C., between 400° C. and 1200° C. or between 500° C. and 100° C., and most preferably between 600° C. and 900° C. or between 650° C. and 800° C. to cause the poly(p-xylylene) dimer to decompose.

Prior to decomposing a poly(p-xylylene) dimer, the method may comprise evaporating the poly(p-xylylene) dimer. The method may comprise heating the poly(p-xylylene) dimer to a temperature of at least 60° C., more preferably at least 80° C., at least 100° C. or at least 500° C., and most preferably at least 120° C. or at least 130° C. to cause the poly(p-xylylene) dimer to evaporate. The method may comprise heating the poly(p-xylylene) dimer to a temperature between 60° C. and 650° C., more preferably between 80° C. and 500° C., between 100° C. and 300° C. or between 500° C. and 100° C., and most preferably between 120° C. and 250° C. or between 130° C. and 200° C. to cause the poly(p-xylylene) dimer to evaporate.

In some embodiments, the second feedstock is a feedstock configured to provide a diamond-like carbon (DLC) layer. Accordingly, in a preferred embodiment, the method provides a multi-layered coating on a substrate, wherein the multi-layered coating comprises a first layer comprising poly(p-xylylene) and a second layer comprising DLC.

In some embodiments, the final feedstock is a feedstock configured to provide a diamond-like carbon (DLC) layer.

In alternative embodiments, the final feedstock is a feedstock configured to provide a metal or metalloid containing layer. The metal or metalloid containing layer may comprise a metal, a metalloid, a metal suboxide or a metalloid suboxide. A suboxide may be understood to be a metal or metalloid rich oxide, e.g. it may have a higher proportion of metal or metalloid than a normal oxide. Preferably, the metal or metal suboxide is titanium (Ti) or titanium suboxide (TiOₓ). It may be appreciated that a normal titanium oxide can be viewed as titanium dioxide (TiO₂). Accordingly, the titanium suboxide may have formula TiOₓ where x is less than 2, x may be between 0 and 1.9.

In embodiments where a feedstock is a feedstock configured to provide a metal or metalloid containing layer, subsequent to the feedstock being fed to the substrate and the metal or metalloid containing layer being formed thereon, the method may comprise:
feeding oxygen to the substrate such that the plasma ionises and/or activates the oxygen; and
allowing the ionised and/or activated oxygen to contact the metal or metalloid containing layer, and thereby oxidise the metal or metalloid containing layer.

Accordingly, the layer may comprise an oxidised metal or metalloid, and preferably comprises titanium dioxide (TiO₂). Advantageously, this alters the optical properties of the layer. In some embodiments, this layer may be the final layer. However, it will be appreciated that in some embodiments, it may be desirable for an intermediate layer to comprise an oxidised metal or metalloid.

The pressure in the deposition chamber may not rise above 700 Torr between the final feedstock and the oxygen being fed into the deposition chamber and/or while the oxygen is being fed into the deposition chamber. The pressure in the deposition chamber may not rise above 600 Torr, above 500 Torr or above 400 Torr between the final feedstock and the oxygen being fed into the deposition chamber and/or while the oxygen is being fed into the deposition chamber, preferably the pressure in the deposition chamber does not rise above 300 Torr, above 200 Torr or above 100 Torr between the final feedstock and the oxygen being fed into the deposition chamber and/or while the oxygen is being fed into the deposition chamber, more preferably the pressure in the deposition chamber does not rise above 80 Torr or above 60 Torr between the final feedstock and the oxygen being fed into the deposition chamber and/or while the oxygen is being fed into the deposition chamber, and most preferably the in the deposition chamber pressure does not rise above 40 Torr or 20 Torr between the final feedstock and the oxygen being fed into the deposition chamber and/or while the oxygen is being fed into the deposition chamber.

The inventors believe that coated substrates produced according to the method of the first aspect are novel and inventive per se.

Accordingly, in accordance with a second aspect, there is provided a coated substrate obtained or obtainable according to the method of the first aspect.

Advantageously, the adhesion between the layers in the coated substrate is improved over coated substrates which are produced using prior art methods. Accordingly, the coated substrate may be viewed as a supercomposite. Furthermore, the coating may be viewed as forming an integral part of the substrate. For instance, the bonds between the substrate and the coating may be as strong as the bonds within the substrate. Similarly, the bonds between layers of the coating may be as strong as the bonds within a given layer.

In accordance with a third aspect, there is provided an apparatus for providing a multilayer coating onto a substrate, the apparatus comprising:
a deposition chamber;
a vacuum pump configured to reduce the pressure of the deposition chamber to a pressure of less than 10 Torr;
a platen disposed inside the deposition chamber and comprising an electrically conductive material, wherein the platen is electrically connected to an electrical power supply and configured to support a substrate;
an electrode, wherein the electrode is electrically insulated from the platen; and
feed means configured to sequentially feed a plurality of feedstocks into the deposition chamber without the pressure therein rising above 700 Torr between feedstocks being fed into the deposition chamber, whereby each feedstock is configured to provide a coating layer on the substrate such that the sequential provision of the plurality of feedstocks provides a multilayer coating.

The feed means may be configured to sequentially feed the plurality of feedstocks into the deposition chamber without the pressure therein rising above 600 Torr, above 500 Torr or above 400 Torr, preferably without the pressure in the deposition chamber rising above 300 Torr, above 200 Torr or above 100, more preferably without the pressure rising above 80 Torr or above 60 Torr, and most preferably without the pressure rising above 40 Torr or 20 Torr.

The plurality of feedstocks preferably comprises at least two feedstocks, and may comprise at least three, at least four or at least five feedstocks. Accordingly, the feed means may be configured to feed a first feedstock to the platen and then subsequently feed a second feedstock to the platen, wherein the second feedstock is different to the first feedstock. The feed means may then be configured to subsequently feed a third feedstock to the platen or alternatively subsequently feed the first feedstock to the platen a further time. Advantageously, this allows bespoke substrates comprising a plurality of layers to be produced for specific applications.

Preferably, the feedstocks, the electrode, the platen, the substrate and/or the electrical power supply are as defined in relation to the first aspect.

Preferably, the vacuum pump is configured to reduce the pressure of the deposition chamber to a pressure of less than 1 Torr or less than 0.1 Torr, more preferably less than 50 mTorr, less than 40 mTorr, less than 30 mTorr, less than 20 mTorr or less than 10 mTorr, and most preferably less than 5 mTorr or less than 1 mTorr.

In embodiments where the substrate comprises an electrically insulating material, the electrical power supply may be configured to apply electrical power to the platen at a power of between 0.0001 Watts/cm² and 10 Watt/cm², more preferably between 0.001 Watts/cm² and 5 Watt/cm² or between 0.005 Watts/cm² and 1 Watts/cm² and most preferably between 0.01 and 0.5 Watts/cm².

In embodiments where the substrate comprises an electrically conductive material, the electrical power supply may be configured to apply electrical power to an electrically conductive substrate supported by the platen. Preferably, the electrical power supply is configured to apply electrical power to an electrically conductive substrate disposed supported by the platen at a power of between 0.0001 Watts/cm² and 10 Watt/cm², more preferably between 0.001 Watts/cm² and 5 Watt/cm² or between 0.005 Watts/cm² and 1 Watts/cm² and most preferably between 0.01 and 0.5 Watts/cm².

In embodiments where the platen comprises a plate configured to receive the substrate thereon, the apparatus may comprise rotator configured to turn the substrate over on the plate. Advantageously, the rotator is configured to expose an underside of the substrate, allowing it to be coated.

The feed means may comprise a first feed means configured to feed a poly(p-xylylene) monomer to the platen, and a second feed means configured to feed one or more feedstocks to the platen. Preferably, the one or more feedstocks do not comprise a poly(p-xylylene) monomer.

The apparatus may comprise a pyrolysis oven. The apparatus may comprise a temperature sensor disposed in the pyrolysis oven. Preferably, the first feed means comprises a conduit which extends between the pyrolysis oven and the deposition chamber. The pyrolysis oven may comprise a first heating element configured to heat the pyrolysis oven to a first elevated temperature. The first elevated temperature should be sufficient to cause pyrolysis of a poly(p-xylylene) dimer. Accordingly, the first elevated temperature may vary depending upon which poly(p-xylylene) dimer the apparatus is configured to be used with. The required pyrolysis temperatures will be well known by the skilled person. For instance, the pyrolysis temperature for both Parylene N™ and Parylene C™ is 650° C., the pyrolysis temperature of Parylene HT™ is 700° C. and the pyrolysis temperature of Parylene D™ is 750° C. The first elevated temperature may be at least 200° C., more preferably at least 300° C., at least 400° C. or at least 500° C., and most preferably at least 600° C. or at least 650° C. In some embodiments, the first elevated temperature may be at least 700° C., at least 750° C. or at least 800° C. The first elevated temperature may be between 200° C. and 1500° C., more preferably between 300° C. and 1400° C., between 400° C. and 1200° C. or between 500° C. and 1000° C., and most preferably between 600° C. and 900° C. or between 650° C. and 800° C. Advantageously, the pyrolysis oven is configured to cause the dimer to decompose to provide the monomer. Preferably, the apparatus comprises a further feed means configured to feed the poly(p-xylylene) dimer into the pyrolysis oven.

The first feed means may comprise a vacuum valve. It may be appreciated that a vacuum valve may otherwise be known as a trickle vale, and is used to maintain an airlock seal. Accordingly, the vacuum valve may be configured to reversibly create an airlock seal between the pyrolysis oven and the deposition chamber.

The apparatus may comprise a vaporiser oven. The apparatus may comprise a temperature sensor disposed in the vaporiser oven. Preferably, the further feed means comprises a conduit which extends between the vaporiser oven and the pyrolysis oven. The vaporiser oven may comprise a second heating element configured to heat the vaporiser oven to a second elevated temperature. The second elevated temperature should be sufficient to cause evaporation of the poly(p-xylylene) dimer. Accordingly, the second elevated temperature may vary depending upon which poly(p-xylylene) dimer the apparatus is configured to be used with. The required evaporation temperatures will be well known by the skilled person. For instance, the evaporation temperatures for [2.2]paracyclophane, dichloro[2,2]paracyclophane, tetrachloro[2.2]paracyclophane and octafluoro[2.2]paracyclophane are all between 150° C. and 300° C. The second elevated temperature may be at least 6° C., more preferably at least 80° C., at least 100° C. or at least 500° C., and most preferably at least 120° C. or at least 130° C. Preferably, the second heating element is configured to heat the vaporiser oven to a temperature between 60° C. and 650° C. Preferably, the second heating element is configured to heat the vaporiser oven to a temperature of between 80° C. and 500° C. or between 100° C. and 300° C., and most preferably between 12° C. and 250° C. or between 13° C. and 200° C. Advantageously, the vaporiser oven is configured to vaporise the dimer.

The apparatus may comprise a controller.

The controller may be configured to activate the vacuum pump when a user initiates a coating cycle.

The controller may be configured to cause the feed means to feed a first feedstock to the platen. Preferably, the controller is configured to cause the feed means to feed a first feedstock into the deposition chamber.

The apparatus may comprise a pressure sensor. The pressure sensor may be disposed in the deposition chamber. The controller may be configured to monitor the pressure in the deposition chamber. The controller may be configured to cause the feed means to start feeding a feedstock into the deposition chamber after the pressure in the deposition chamber has fallen below a predetermined pressure. The predetermined pressure may be a pressure of less than 10 Torr, less than 1 Torr or less than 0.1 Torr, more preferably less than 50 mTorr, less than 40 mTorr, less than 30 mTorr, less than 20 mTorr or less than 10 mTorr, and most preferably less than 5 mTorr or less than 1 mTorr.

The controller may be configured to activate the electrical power supply, after the feed means has started feeding a feedstock into the deposition chamber and when the pressure in the deposition chamber has risen above a predetermined pressure. The predetermined pressure may be a pressure of at least 1 mTorr, more preferably at least 10 mTorr, at least 20 mTorr, at least 30 mTorr, at least 40 mTorr or at least 50 mTorr, and most preferably at least 0.1 Torr, at least 1 Torr or at least 10 Torr. Advantageously, activating the power supply will cause a layer to deposit on the substrate.

The apparatus may comprise a monitor configured to monitor the thickness of a layer deposited on the substrate. The monitor may comprise a crystal film thickness monitor.

The controller may be configured to finish a coating cycle a predetermined time after the electrical power supply has been activated, when the layer deposited on the substrate has reached a desired thickness and/or when it receives an input from a user.

Alternatively, in embodiments where the platen comprises a plate configured to receive the substrate thereon, the controller may be configured to activate the rotator cycle a predetermined time after the electrical power supply has been activated, when the layer deposited on the substrate has reached a desired thickness and/or when it receives an input from a user. Advantageously, the rotator would turn the substrate over exposing the uncoated side so that a layer could be deposited thereon. The controller may then be configured to finish a coating cycle a predetermined time after the substrate has been turned over, when the layer deposited on the second side of the substrate has reached a desired thickness and/or when it receives an input from a user.

It may be appreciated that the predetermined time will vary depending upon a number of facts including the geometry of the substrate being coated and the desired thickness of the deposited layer. Accordingly, it may be appreciated that the predetermined time may be determined by the skilled person. In one embodiment, the predetermined time may be at least 5 minutes, more preferably at least 30 minutes, at least 1 hour or at least 1.5 hours, and most preferably at least 2 hours. In one embodiment, the predetermined time may be less than 12 hours, more preferably less than 6 hours, less than 5 hours or less than 4 hours, and most preferably less than 3 hours. In one embodiment, the predetermined time may be between 1 minute and 12 hours, more preferably between 30 minutes and 6 hours, between 1 hour and 5 hours or between 1.5 hours and 4 hours, and most preferably between 2 and 3 hours.

It may be appreciated that the desired thickness of the deposited layer will vary depending upon the substrate. If the substrate comprises a smooth surface, the deposition layer will preferably be at least 10 nm may be applied. Accordingly, in some embodiments, a deposition layer of between 10 nm and 1 μm may be applied. In some embodiments, a thicker deposition layer may be desirable. Accordingly, the deposition layer may be at least 1 μm, and may be between 1 μm and 100 μm. Alternatively, if the substrate comprises a rough surface, then it may be desirable for the thickness of the deposition layer to be thicker than the depth of the roughness of the surface of the substrate.

When the controller finishes a coating cycle it may be configured to deactivate the electrical power supply and/or cause the feed means to stop feeding a feedstock into the deposition chamber.

The controller may be configured to initiate a further coating cycle. Accordingly, the controller may be configured to cause the feed means to start feeding a different feedstock into the deposition chamber after the pressure in the deposition chamber has fallen below a predetermined pressure. The predetermined pressure may be as defined above. The controller may be configured to activate the electrical power supply, after the feed means has started feeding the different feedstock into the deposition chamber and when the pressure in the deposition chamber has risen above a predetermined pressure. The predetermined pressure may be as defined above.

The controller may be configured to cause the feed means to feed a feedstock comprising a poly(p-xylylene) monomer into the deposition chamber. In some embodiments, the first feed stock may comprise the feedstock comprising a poly(p-xylylene) monomer.

The controller may cause the feed means to feed a feedstock comprising a poly(p-xylylene) monomer into the deposition chamber by opening the vacuum valve.

Alternatively, or additionally, the controller may cause the feed means to feed a feedstock comprising a poly(p-xylylene) monomer into the deposition chamber by activating the first heating element.

The controller may be configured to monitor the temperature in the pyrolysis oven. The controller may be configured to activate the second heating element when the temperature in the pyrolysis oven has risen above a predetermined temperature. The predetermined temperature may be a temperature of at least 200° C., more preferably at least 300° C., at least 400° C. or at least 500° C., and most preferably at least 600° C. or at least 650° C. In some embodiments, the predetermined temperature may be at least 700° C., at least 750° C. or at least 800° C.

The controller may be configured to maintain the pyrolysis oven within a predetermined temperature range. The predetermined temperature range is preferably between 200° C. and 1500° C., more preferably between 300° C. and 1400° C., between 400° C. and 1200° C. or between 500° C. and 100° C., and most preferably between 600° C. and 900° C. or between 650° C. and 800° C.

The controller may be configured to monitor the temperature in the vaporiser oven. The controller may be configured to maintain the vaporiser oven within a predetermined temperature range. The predetermined temperature range is preferably between 60° C. and 650° C., more preferably between 80° C. and 50° C., between 100° C. and 300° C. or between 500° C. and 100° C., and most preferably between 120° C. and 250° C. or between 130° C. and 200° C.

In a preferred embodiment, the controller is configured to open the vacuum valve after it has activated the second heating element.

The controller may be configured to close the vacuum valve, and thereby cause the feed means to stop feeding the feedstock comprising a poly(p-xylylene) monomer into the deposition chamber. It may be appreciated that closing the vacuum valve creates an airlock seal between the deposition chamber and the pyrolysis oven.

The feed means may comprise a conduit configured to feed one or more feedstocks into the deposition chamber. The conduit may extend between the deposition chamber and a store. The store may comprise a feedstock or a component thereof. Accordingly, the store may comprise a gas cylinder or a liquid tank. The feed means may comprise a valve disposed in the conduit. The valve may be configured to switch between first and second configurations, wherein in the first configuration the valve prevents the flow of a fluid from the store to the deposition chamber, and in the second configuration allows the flow of the fluid from the store to the deposition chamber. The valve may be a flow control valve, and more preferably is a mass flow controller (MFC).

The controller may be configured to switch the valve to the second configuration, and thereby cause the feedstock to be fed into the deposition chamber. The controller may be configured to control the flow rate of the feedstock into the deposition chamber. The controller may be configured to switch the valve to the first configuration, and thereby cause the feed means to stop feeding the feedstock into the deposition chamber.

The feed means may comprise a plurality of conduits extending between the deposition chamber and a plurality of stores. The feed means may further comprise a plurality of valves, whereby a valve is disposed in each conduit. The controller may be configured to selectively open and close different valves, to thereby cause different feedstocks to selectively flow into the deposition chamber.

After the apparatus has run a predetermined number of coating cycles, the controller may be configured to vent the apparatus. The controller may be configured to vent the apparatus after it has deactivated the power supply. Preferably, venting the apparatus comprises raising the pressure in the deposition chamber to about atmospheric pressure. Advantageously, a user can then remove the substrate from the deposition chamber and place a further substrate to be coated substrate therein. If the vacuum valve is closed, then the vaporiser oven and pyrolysis oven remain under vacuum.

Alternatively, the controller may be configured to power down the apparatus. Accordingly, the controller may be configured to deactivate the first and second heating elements. The controller may be configured to open the vacuum valve when the temperature in the vaporiser oven and/or in the pyrolysis oven falls below a predetermined temperature. The predetermined temperature may be less than 100° C., more preferably the predetermined temperature is less than 80° C. or less than 60° C., and most preferably is less than 50° C. Advantageously, the controller could thereby vent the vaporiser oven and the pyrolysis oven to restock the feed source.

### BRIEF DESCRIPTION OF THE DRAWINGS

All features described herein (including any accompanying claims, abstract and drawings), and/or all of the steps of any method or process so disclosed, may be combined with any of the above aspects in any combination, except combinations where at least some of such features and/or steps are mutually exclusive.

For a better understanding of the invention, and to show how embodiments of the same may be carried into effect, reference will now be made, by way of example, to the accompanying drawings, in which:—

FIG. 1 is a schematic diagram of an apparatus for depositing a multilayer film on a component;

FIG. 2 shows a platen configured to support the component;

FIG. 3 is a schematic diagram of an alternative apparatus for depositing a multilayer film on a component;

FIG. 4 shows post processing results and generated stresses for carbon reinforced fibre polymer (CFRP) composites comprising layers disposed using the apparatus shown in FIG. 1;

FIG. 4A shows the observed stresses where a diamond-like carbon (DLC) layer or any hard coating is deposited directly on the on the CFRP substrate; and

FIG. 4B shows the observed stresses where a poly (para-xylylene) layer is deposited directly on the on the CFRP substrate and a DLC or any hard layer is disposed thereon;

FIG. 5 is a scanning electron microscope (SEM) image of a composite comprising a CFRP substrate where a DLC layer has been applied directly thereto, and shows adhesion failure of the DLC layer due to extrinsic stress within the composite structure;

FIG. 6 is a graph showing the mean coefficient of thermal expansion (CTE) at room temperature for coated and uncoated composite structures comprising unidirectional (UD) CFRPs where the plies were oriented in 0° and 90°;

FIGS. 7A and B are SEM images of the top view of a coated and loaded sample;

FIGS. 8A and B are SEM images of the inclined view of edge of two coated and loaded samples;

FIGS. 9A and B are SEM images showing coated samples which were tested until rupture;

FIG. 10 is a photograph showing installed samples on a vacuum before UV radiation;

FIG. 11A shows measured reflection curves for coated and uncoated LOK samples obtained before and after the samples were exposed to UV radiation; and

FIG. 11B shows transmission curves for coated and uncoated LOK samples obtained before and after the samples were exposed to UV radiation;

FIG. 12 is a schematic diagram of the European Space Research and Technology Centre (ESTEC) Low Earth Orbit Facility (LEOX);

FIG. 13 is a photograph showing the sample plate assembly for exposure to atomic oxygen (ATOX), a key at the top right identifies the location of the different samples;

FIG. 14 shows measured and calculated ATOX fluence maps for the (A) first and (B) second runs;

FIG. 15 shows graphs showing the change in mass observed for samples exposed to ATOX;

FIG. 16 shows the relative ATOX erosion data with respect to Kapton® HN reference samples for various substrates coated with protective layers, where To indicates that the sample had no coating, T2 indicates that the sample was coated with coating type 2 and T3 indicates that the sample was coated with coating type 3. In each case the value on the left, identified as Int, is the mass change after the 1^{st} exposure and the value on the right, identified as EoT, is the mass change after the 2^{nd} and last exposure;

FIG. 17 shows images and data obtained using a confocal laser scanning microscope for an uncoated Rexolite® sample which was exposed to UV irradiation and ATOX;

FIG. 18 shows images and data obtained using a confocal laser scanning microscope for a coated Rexolite® sample which was exposed to UV irradiation and ATOX;

FIG. 19 shows two components, each comprising a layered coating which has been deposited in accordance with the invention;

FIG. 20 shows electron microscopy images of a cross section of (A) a multi-layer coating deposited with vacuum interruption highlighting layer delamination; or (B) a multi-layer coating deposited without vacuum interruption; and

FIG. 21 shows electron microscopy images of a top surface of (A) a multi-layer coating deposited with vacuum interruption highlighting pinhole generation; or (B) a multi-layer coating deposited without vacuum interruption.

### DETAILED DESCRIPTION

### Example 1—Apparatus and Method for Depositing a Multilaver Film on an Electrically Conductive Component

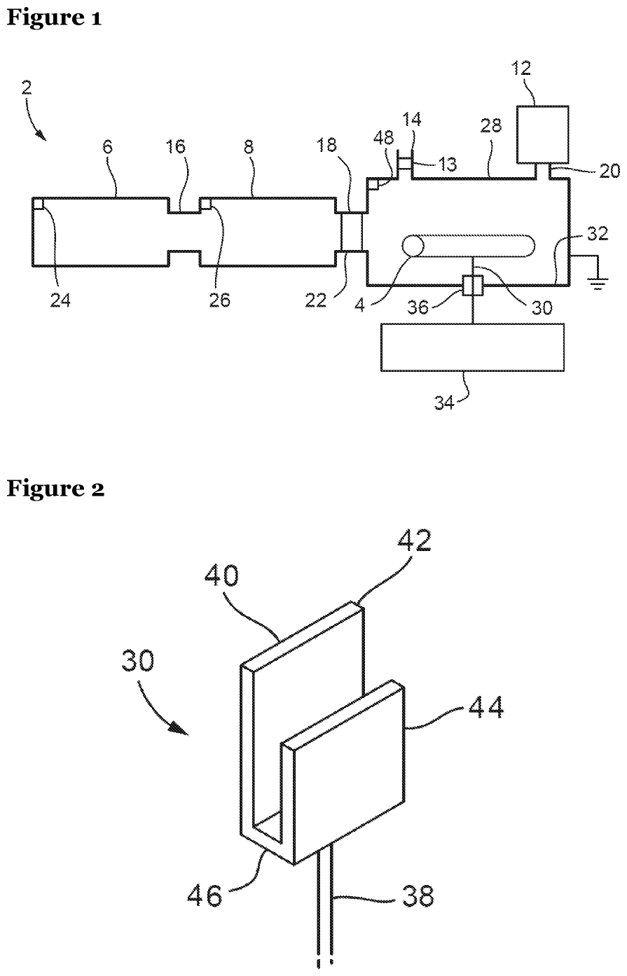

FIG. 1 shows an apparatus 2 configured to deposit a multilayer film on an electrically conductive component 4. The apparatus comprises a vaporiser oven 6, a pyrolysis oven 8, a deposition chamber 10, a vacuum pump 12 and a feed means 14 configured to feed components into the deposition chamber 10. A first conduit 16 extends between the vaporiser oven 6 and the pyrolysis oven 8, a second conduit 18 extends between the pyrolysis oven 8 and the deposition chamber 10 and a third conduit 20 extends between the deposition chamber 10 and the vacuum pump 12. A vacuum valve 22 is disposed in the second conduit 18. The feed means 14 comprises a shut-off valve 15 and one or more mass flow controllers (not shown) which regulate the flow of fluids from the feed means 14 into the deposition chamber 10.

The vaporiser oven 6 comprises a first heating element (not shown) configured to heat the vaporiser oven 6 to a temperature between 130° C. and 200° C. and a first temperature sensor 24 configured to sense the temperature therein. Similarly, the pyrolysis oven 8 comprises a second heating element (not shown) configured to heat the pyrolysis oven 8 to a temperature between 650° C. and 800° C. and a second temperature sensor 26 configured to sense the temperature therein.

The deposition chamber 10 comprises a metallic housing 28. As shown in FIG. 1, the metallic housing 28 is earthed.

As shown in FIG. 1, an electrically conductive component 4 may be disposed in the deposition chamber 10. The component 4 is disposed on a platen 30, which holds the component 4 above the base 32 of the deposition chamber 10 and electrically connects the component 4 to a radio-frequency electrical power supply 34. The radio-frequency power supply 34 used by the inventors operated at a frequency of 13.56 MHz, as this is an industrial, scientific and medical (ISM) radio band, and so will not disrupt radio communication. The component 4 is electrically insulated from the metallic housing 28 due to an insulating material 36 being disposed between the platen 30 and the housing 28.

As shown in FIG. 2, the platen 30 may comprise a metallic rod 38 with a resilient metallic clip 40 disposed thereon. The metallic clip 40 comprises spaced apart flanges 42, 44 joined by a connecting portion 46. A portion of component 4 can slot between the flanges 42, 44, and the platen 30 is thereby able to support the component 4. The metallic clip 40 is sized so as to contact as little of the component 4 as possible, and typically contacts less than 1% of the surface of the component 4.

The apparatus 2 shown in Figure can apply a variety of coatings to the component 4. The user would initially load the component 4 into the deposition chamber 10 and positions it on the platen 20 to connect it electrically to the radio-frequency electrical power supply 24.

It is noted that, a poly(p-xylylene) layer can act as a buffer later between a carbon fibre reinforced polymer (CFRP) and further layers. Accordingly, the apparatus could be configured to apply a poly(p-xylylene) polymer layer first.

If the user wishes the apparatus to coat a component 4 with a film of poly(p-xylylene) polymer, then the user would also loads a poly(p-xylylene) dimer into the vaporiser oven 6. The quantity the user loads depends upon the size of the component 4 to be coated. The inventors have typically used between 1 to 20 grams, and have found that this is sufficient to coat a component 4 with complex three dimensional geometry and a dimension of between about 10 and 20 cm mark, or a flat component 4 with a dimension of about 50 cm. It will be appreciated that these are examples only, and the method described herein could be used to apply a coating to a component of any size.

The user can also place a small amount of an adhesion promotion agent, such as A-174, in the deposition chamber 10. The adhesion promotion agent can be provided in an open container, such as a petri dish. The amount of adhesion promotion agent required would depend upon the size of the component 4, but the inventors have typically used about 3 ml. Alternatively, the adhesion agent could be injected into the deposition chamber 10. For instance, an open container containing the adhesion agent could be placed in a further chamber, where the further chamber is attached by a conduit to the deposition chamber. By opening and closing a valve disposed in the conduit, a user could control whether or not the adhesion agent is present in the deposition chamber.

It should be noted, that the use of a plasma, as described below, enhances the reactivity of the monomers and activates the surface of the component 4.

Accordingly, the adhesion of the poly(p-xylylene) polymer is stronger than was possible previously. The inventors have found that good adhesion may be achieved without the need for an adhesion agent. Accordingly, the adhesion agent may not be required.

The user then hermetically seals the apparatus 2, ensures that the vacuum valve 18 is open and then activates the vacuum pump 12 to cause the pressure within the vaporiser oven 6, pyrolysis oven 8 and deposition chamber 10 to reduce to lower than 10-3 Torr. This causes the adhesion agent, if present, to evaporate and coat the inside of the deposition chamber 10 and component 4.

The user then activates the second heating element to heat the pyrolysis oven 8 to a temperature between 650° C. and 800° C. Once the vaporiser oven 8 has reached the desired temperature, the user activates the first heating element to heat the vaporiser oven 6 to a temperature between 130° C. and 200° C. As the temperature in the vaporiser oven 6 rises the poly(p-xylylene) dimer disposed therein evaporates. Due to the vacuum, the parylene dimer flows into the pyrolysis oven 8, and the high temperature therein causes the dimer to decompose into two monomer molecules. The monomer molecules continue to flow into the deposition chamber 10, raising the pressure therein.

When a pressure sensor 48 disposed in the deposition chamber 10 records that the pressure has reached 50 mTorr, the user turns-on the radio-frequency electrical power supply 34. The electrical power delivered by the radio-frequency electrical power supply 34 is typically 0.1 Watts/cm2. Due to the metallic housing 28 of the deposition chamber 10 being grounded, it acts as a virtual electrode and a plasma is created around the component 4. The plasma ionises and/or activates the monomers, typically causing them to become positively charged. The plasma also activates the surface of the component 4. The ionised monomers are attracted to the component 4, deposit thereon and polymerise to form a poly(p-xylylene) polymer coating.

During deposition, other gases can be added to the deposition chamber 10 through the feed means 14. These gases could include a hydrocarbon, such as acetylene, and/or an organometallic compound, such as tetraethyl orthosilicate (TEOS), and/or titanium isopropoxide (TIPP). The additives can be present in the deposition chamber 10 throughout the deposition process so they are disposed throughout the coating to add functionality. Alternatively, they may be added at selected times to produce a multi-layer coating.

Once the desired coating thickness has been reached, as determined by a crystal film thickness monitor (not shown) disposed in the deposition chamber 10, the user can prevent further deposition of the poly(p-xylylene) polymer coating by closing the vacuum valve 18 to isolate the ovens 6, 8. If no further layers of poly(p-xylylene) polymer will be required, the user could deactivate the heating elements in the ovens 6, 8.

The user can then feed a feedstock for a second layer into the deposition chamber 10 through the feed means 14.

In some embodiments, the second layer may comprise diamond-like carbon (DLC) layer. Advantageously, this layer provides a moisture and contamination barrier by preventing the ingress of moisture to the component 4 as well as suppress volatile compound outgassing therefrom. Accordingly, the method may comprise feeding mixture of hydrogen gas and a hydrocarbon gas (e.g. methane, acetylene, etc.) into the deposition chamber 10. Typically, the hydrocarbon comprises about 1-20% (v/v) of the gas mixture, but it can be present in higher amounts. The gas mixture may further comprise gases such as argon, helium and nitrogen. Alternatively, or additionally, if a fluorine source is provided then the layer deposited will be fluorinated DLC. This could be achieved by selecting a fluorinated hydrocarbon as the carbon feedstock or adding fluorine gas to the gas mixture.

Again, due to the presence of the plasma, a DLC layer will form directly on the poly(p-xylylene) layer. Once the desired coating thickness has been reached the user can halt the flow of the gas mixture into the chamber.

In some embodiments, the user may then want to form a further layer of poly(p-xylylene) on the component 4. They can do this by opening the vacuum valve 18 and allowing a further layer of poly(p-xylylene) to form. The user may then continue to add alternating layers of poly(p-xylylene) and DLC layer on the component, and they can do this as described above without breaking the vacuum within the deposition chamber 10.

Alternatively, or additionally, the user may wish to add alternative layers to the composite or additivities to the above described layers. These alternative layers and/or additives could comprise inorganic compounds, metals and/or metal oxides. For example, a metal and/or inorganic oxide layer could comprise TiOₓ and/or SiOₓ. Advantageously, this layer and/or additive provides protection against atomic oxygen, enhanced ultraviolet (UV) protection, thermal and ionizing irradiation stability. The additional layer and/or additive also allows a user to vary the thermo-optical and electrical properties of the resultant component. For instance, it may be possible to provide low dielectric properties.

As described above, an appropriate feedstock will be fed into the into the deposition chamber 10 and, due to the presence of the plasma, will form the desired layer on the substrate 4. For instance, if the user wanted to provide a metal layer on the substrate they would feed a feedstock comprising a metal source. This could be a feedstock comprising an organometallic. The feedstock would comprise atoms or ions of the desired metal, which could be tungsten (W), titanium (Ti), niobium (Nb), tantalum (Ta), nickel (Ni), molybdenum (Mo) or aluminium (Al). Alternatively, or additionally, if the user wanted to provide an inorganic layer, they could provide a feedstock comprising one or more inorganic compounds configured to provide an inorganic layer. The resultant layer could comprise silicon carbide (SiC), silicon oxide (SiOx), silicon Oxynitride (SiOxNy), titanium oxynitride (TiOxNy), titanium nitride (TiN), titanium oxide (TiOx), silicon nitride (Si3N4) or aluminium oxide (Al2O3).

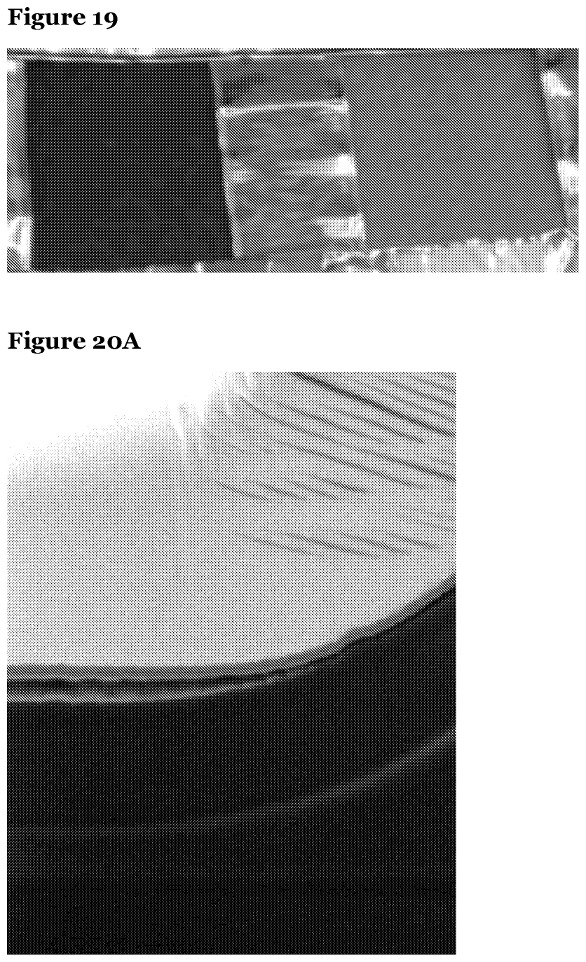

In some embodiments, the final layer may comprise a metal or metal oxide layer, such as titanium (Ti) or a titanium suboxide (TiOx). After this final layer has been deposited, the user may feed oxygen (O2) into the deposition chamber 10. The presence of the plasma will cause an oxide layer to form on the component, converting the Ti or TiOx to titanium dioxide (TiO2). FIG. 19 is a photo, showing two components, each comprising a layered coating which has been deposited as described above. The final layer for the substrate on the left is a TiOx layer. The final layer deposited on the substrate on the right was also TiOx, but this has subsequently been treated with an oxygen plasma so that the final layer actually comprises TiO2. It is clear that the oxygen plasma treatment has altered the optical properties of the final layer and caused it to become white. Advantageously this allows thermal surface controlling, where less heat will be absorbed into the material and much more emitted (lower absorptivity and higher emissivity). This could enable a substrate coated with this layer to withstand a prolonged exposure to harsh thermal environment conditions.

Once all of the required layers have been deposited the user can stop the process. The user can first turn-off the radio-frequency electrical power supply 24. If the heating elements are still on and the vacuum valve 18 is open, the user can then turn-off these off both heating elements. When the vaporiser oven 6 and pyrolysis oven 8 have both cooled to a temperature below 50° C., the user stops the vacuum pump 12 and vents the deposition chamber 10 to ambient pressure. The user can then open the deposition chamber 10 and retrieve the coated component 4.

Alternatively, the ovens 6, 8 take a long time to cool. Alternatively, the user could close the vacuum valve 18, or leave it closed if it already was, to isolate the ovens 6, 8. The user then stops the vacuum pump 12 and vents the deposition chamber 10 to ambient pressure. The user can then open the deposition chamber 10 and retrieve the coated component 4. The user could then place a further component 4 in the deposition chamber to be coated.

### Example 2—Apparatus and Method for Depositing a Multilayer Film on an Electrically Insulating Component

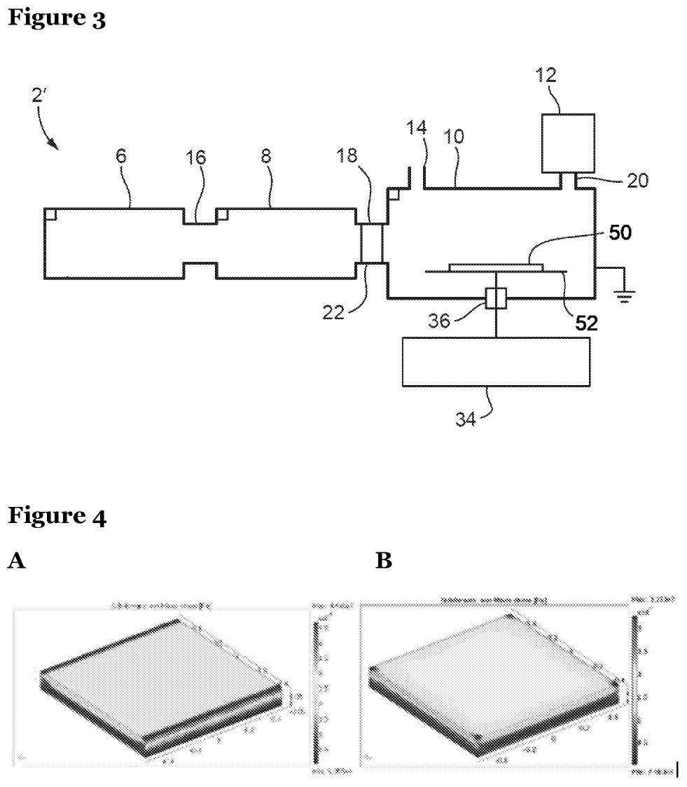

FIG. 3 shows an alternative apparatus 2′ configured to a multilayer film on an electrically insulating component 4. As shown in the Figure, the component 50 has a thin width and is flat. The exact thickness of the component 50 will vary. For instance, it is noted that the inventors have successfully used this method to coat components thicknesses between 2 and 3 cm. It will be appreciated that thicker components could be coated if a stronger electrical field is used.

Similarly, to the apparatus 2 described in example 1, the apparatus 2′ comprises a vaporiser oven 6, a pyrolysis oven 8, a deposition chamber 10, a vacuum pump 12 and a feed means 14. The various components are interconnected by conduits 16, 18, 20 as explained above.

As shown in FIG. 3, the deposition chamber comprises a platen 52 which defines a flat platform configured to receive the component 50 thereon. The platen 52 is electrically connected to a radio-frequency electrical power supply 34, which is as defined in example 1. The platen 52 is electrically insulated from the metallic housing 28 due to an insulating material 36 being disposed between the platen 20 and the housing 26.

To coat a component 50 with a layer the user follows the method described in the first example. Once the desired coating thickness has been reached, rotation equipment (not shown) disposed within the deposition chamber 10 rotates the component without the need to break the vacuum and optionally without any input from the user.

Once both sides of the component have been coated, the user can then apply one or more further coatings to the component. Once the desired number of layers have been applied, the user can vent the apparatus 2′ as described in Example 1.

### Example 3—Control of Stress of for a Diamond-Like Carbon (DLC) Coating

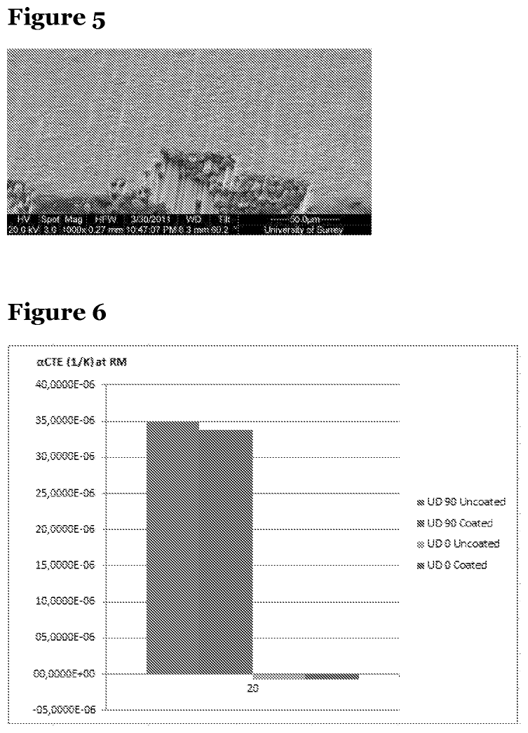

A diamond-like carbon (DLC) coating was applied to CFRP composites using the apparatus and method described in example 1. As shown in FIG. 4A, high stresses on the outer edges of the samples due to poor thermo-mechanical and thus volumetric coupling were observed. As shown in FIG. 5, these stresses can cause adhesion failure of the deposited layer.

Accordingly, the inventors chose to deposit a buffer layer comprising poly (para-xylylene) between the CFRP substrate and the DLC layer. As shown in FIG. 4B, this combination lowered the observed stress. By using a multilayer coating structure, the inventors have found that it is possible to reduce the overall stress level to a negligible level of MPa, thus avoiding the high extrinsic stress that can cause poor adhesion to the substrate.

### Example 4—Coefficients of Thermal Expansion (CTE), Coefficients of Moisture Expansion (CME) and Stress Monitoring

Materials and Methods

To enable the measurement of thermal and moisture expansion, a special Netzsch, high precision dilatometer which is constructed to measure composites and polymers was used. This method enabled the inventors to study length change phenomena of materials, and thus providing information regarding their thermal behaviour, process parameters or sintering (and curing) kinetics. Thermal expansion of the samples during heating was monitored by the displacement system. Due to wide dynamic range, it enabled the measurement soft or hard samples without impairment of their properties.

A high resolution displacement transducer ensures resolution of 0.125 nm/digit, while the extremely low drift exhibited by the system guarantees very high repeatability, accuracy and long-term stability for temperatures up to 2000° C. These features (especially resolution, accuracy) are crucial to measure high stable materials, and thus investigate difference between coated and coated composite substrates. For these measurements, the samples were prepared with dimensions of 50 mm×12 mm×2 mm, and were cut from manufactured plates, inspected, re-measured and cleaned with isopropan-2-ol (uncoated samples).

Because composites can be designed with a near-zero-coefficient of thermal expansion which is necessary for dimensionally stable structures, 20 unidirectional samples were prepared with plies oriented in 0° and 900 (UD0° and UD90°, respectively).

This enabled the inventors to investigate potential coating effects on CTE and CME for both directions and provide sufficient confidence interval of the test results. Coated samples comprised eight layers where the first layer deposited directly on the CFRP substrate is poly (para-xylylene) and the second layer is DLC. The remaining six layers alternate between poly (para-xylylene) and DLC. The total coating thickness was 2000 nm. The thickness was controlled in-situ during the deposition process, measured by Dektak profilometer from silicon witness samples and correlated with transmission electron microscopy measurements which have been done on cross-section samples.

Results

As shown in FIG. 6, no influence of the coating on the CTE of the composite structures can be observed. This is because the thickness of the coating is very small compared to the thickness of the substrate.

Meanwhile, the moisture desorption/absorption effects were also considered. In particular, the expansion and change in mass as a function of time were monitored. This allowed the inventors to calculate the CME, and this is given below in table 1.

TABLE 1
Measured initial CMEs for uncoated and coated samples

| | Measured CME |
|---|---|
| Sample | (initial moisture ingress) |
| UD90° - Uncoated | −1.77 × 10⁻² |
| UD90° - Coated | 0 |
| UD0° - Uncoated | 4.11 × 10⁻⁴ |
| UD0° - Coated | 0 |

The negative/positive signs are related to shrinkage/expansion of the samples, respectively.

These results demonstrate the capabilities of the coatings in the form of a physical barrier, effectively sealing composite materials, where no variations in mass have been recorded. This improves overall material stability, because CTE is still kept close to zero while CME is reduced.

Finally, the inventors note that mismatch of the thermal expansion that could lead to residual stresses has been avoided by using a buffer layer, which has a similar CTE to polymer matrix itself. In particular, as highlighted above the coatings thickness has been measured by Dektak profilometer, optical microscopy and in-situ quartz oscillator method. In combination with dilatometry the film stresses could be determined according to Stoney's equation:

$${σ}_{f} = \frac{{E}_{s} {h}_{s}^{2}}{6 ( 1 - {V}_{s} )} \frac{{h}_{{f}^{2}}}{{h}_{s}} ( \frac{1}{R} - \frac{1}{{R}_{0}} )$$

This has been carried out for operational environment as for the CTE and CME measurements, while the deflections have been monitored in both directions. The Young modulus and Poisson's ratio have been derived from material data sheet and proven mechanically by tests. Based on this, results were obtained and calculated, giving a value of −112.1 MPa for UD0° and −153.7 for UD90°. This shows that the multilayer coatings are able to reduce the stress in the composite, compared to when a DLC layer is applied without a buffer layer. Furthermore, this result is supported by mechanical, cantilever tests which did not reveal any cracks or delamination.

### Example 5—Determination of Coatings Durability and their Influence on Mechanical Properties of Composites

The composite materials produced according to examples 1 and 2 may be required to carry mechanical loads. Accordingly, it is essential that the mechanical properties of the substrate cannot be deteriorated or otherwise significantly altered by the provision of the protective layers thereon. Accordingly, the inventors investigated the influence of the layers on the mechanical properties of substrates such as flexural strength, complex modulus etc. In addition, coatings durability to mechanical knocks and vibration was examined.

Materials and Methods

In order to determine the mechanical values the common three-point flexural test has been used following DIN EN ISO 14125. This enabled to verify flexural properties of fibre-reinforced plastics composites such as:
Flexural strength σ_{fM}
Flexural strength at break σ_{fB}
Flexural modulus E_{f}
Flexural strain ε_{f}
Flexural stress σ_{sf}
Deflections

This method was used to determine the design/test parameters, screen materials as well as quality-control on coated and uncoated CFRP materials. The CFRP samples were cut to required dimensions according to the standard.

Both UD0° and UD90° composites were prepared, these are class IV and III of materials, respectively (acc. to DIN EN ISO 14125). In total 6 configurations were tested, as shown in table 2.

TABLE 2
Samples tested to determine how the coating effects the mechanical
properties

| Composite | Laminate | Coating structure |
|---|---|---|
| 1 | UD0° | Uncoated |
| 2 | UD90° | Uncoated |
| 3 | UD0° | 4 layers - alternating poly |
| | | (para-xylylene) and DLC |
| 4 | UD90° | 4 layers - alternating poly |
| | | (para-xylylene) and DLC |
| 5 | UD0° | 8 layers - alternating poly |
| | | (para-xylylene) and DLC |
| 6 | UD90° | 8 layers - alternating poly |
| | | (para-xylylene) and DLC |

A minimum 6 samples was tested for each of the above identified composites.

The tests were performed on a Zwick 1474 test machine which had following data:
Load cell: 10 kN
Jig distance for UD0°: material: 80 mm
Jig distance for UD90°: 40 mm
Cross head velocity UD0°: 2 mm/min
Cross head velocity for UD90°: 0.5 mm/min

The parameters were determined for materials and were in line to the standard.

Samples were further investigated in the scanning electron microscope (SEM).

A cantilever vibration test was also conducted, which is more accurate to analyse frequency shift, and thus composite-coating system stiffness behaviour. The samples identified in table 2 were also used in the cantilever vibration tests. All of the samples were cut from CFRP plates, re-measured and selected to ensure similar dimensions, especially thickness for raw materials. Further, they were stored for several weeks to ensure similar conditions, thus maximum moisture content inside. Because no slender beams were used, and the ratio of length to thickness was not dimensionless to obtain negligible shear and rotary effects, a Timoshenko model was used. As a result, a dynamic modulus of composites was determined using a flexural resonance method, and cantilever vibration beam test set-up.

A special vibration bracket was manufactured to ensure stiff fixation of the samples. The samples were screwed with the same torque, which was 2 N/m. A small vibration shaker system V780 was used as an excitation which is designed for qualification tests on components and small assemblies under controlled conditions. It enabled operation in the frequency range of DC to 4000 Hz from either a sine or random. Two input sensors were allocated on the upper and lower parts of the bracket.

Two accelerometers were placed to measure generated peaks, one on the bracket and second on the attached mass at the free-end of the beam. Two runs with each level sequence were done, as follows:
1. With one accelerometer allocated on the vibration bracket
2. With accelerometers both on the vibration bracket and free-end of the vibration beam.

Additional cubic mass was placed on the free-end of the cantilever beam. First the resonance search was performed by using a frequency spectrum of 10-2000 Hz, an amplitude of 0.2 g, a sweep rate of 2 Oct/min and a sine vibration. The resonant frequency was found by determining the peak amplitude of the beam by the system. Following that, each sample was tested with the sequence presented in table 3.

TABLE 3
Test setup for each sample

| Frequency | | Sweep rate | |
|---|---|---|---|
| (Hz) | Amplitude (g) | (Oct/min) | Setup |
| 10-2000 | 0.2 | 2 | One accelerometer + |
| | | | cubic mass |
| 10-2000 | 2 | 2 | One accelerometer + |
| | | | cubic mass |
| 10-2000 | 0.2 | 2 | Two accelerometers + |
| | | | cubic mass |
| 10-2000 | 2 | 2 | Two accelerometers + |
| | | | cubic mass |

The dynamic modulus was determined using the following equation:

$$Ed = {( \frac{L}{λ} )}^{4} * \frac{4 {π}^{2} {Fr}^{2} * ρ A}{I} ,$$

where Fr is the resonant frequency.

Then the loss modulus which comes from the entire system could be calculated based on the frequencies difference (f2,f1) for the given amplitude.

$$El = Ed * ( \frac{f 2 - f 1}{fr} )$$

The dynamic modulus at the resonant frequencies was calculated with the correction factors for the rotary inertia and shear deformation according to the Timoshenko (Phil. Mag., Ser. 6, Vol. 41, 744-746, (1921)).

Results

Based upon known flexural properties of the manufactured composites as well as several control tests which were performed on uncoated CFRP samples, first a few coated samples were burdened up to approximately 80% of the maximum strength to investigate potential crack on the coating. Intermediate visual inspection was done followed by scanning electron microscope investigation.

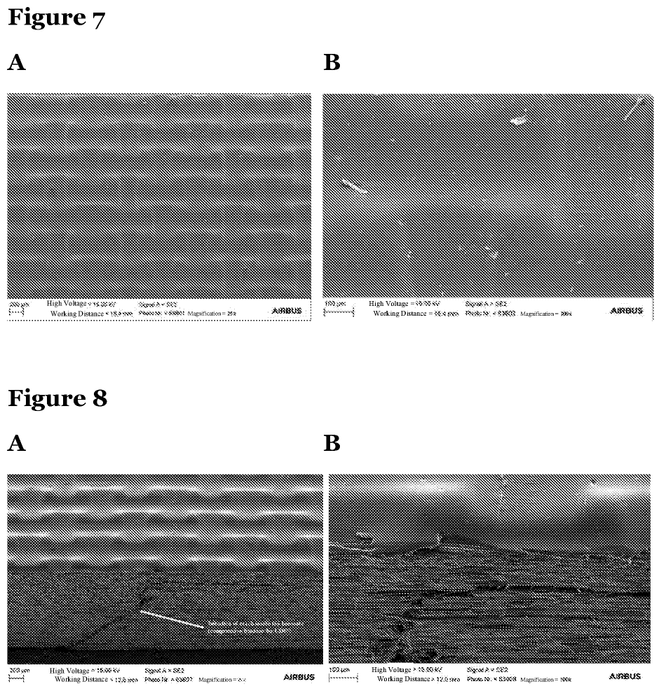

As shown in FIG. 7, the laminate structure comprising the alternating poly (para-xylylene) and DLC layers did not crack or delaminate when a load of up to 260 N was applied. However, as shown in FIG. 8, this force was sufficient to cause ruptures to appear within the CFRP structure. These findings confirm the very robust structure and mechanical integrity of the multilayer coatings—composite system. In fact, the inventors found that that the presence of the layers on the composite had a negligible effect on the flexural strength of the composite structure, with the coated samples performing the same as the uncoated samples.

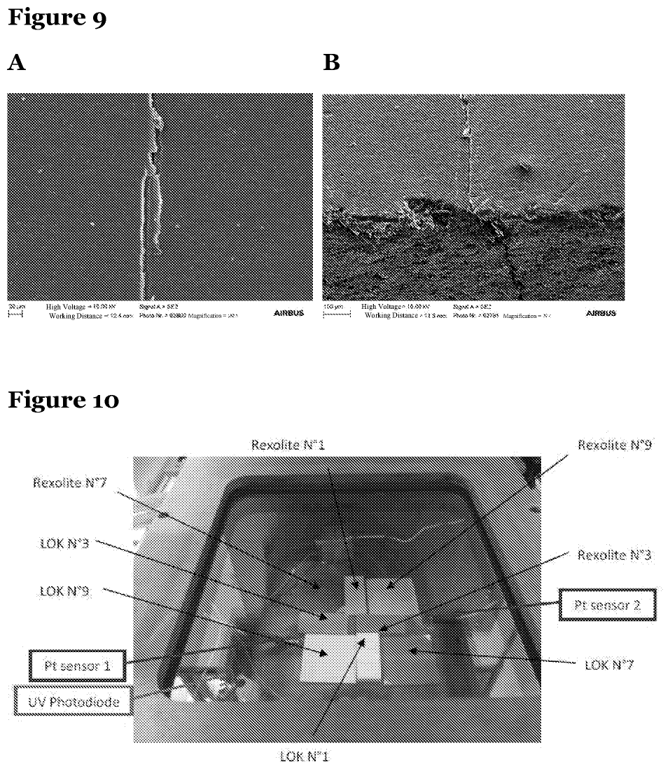

The adhesion of coated samples was tested by the tape test after loading and no failures were observed. Furthermore, the rupture tests showed that there is no multi-cracking or enhanced delamination, flaking of the coatings which remained intact along the surface, see FIG. 9.

Using the above methods, the inventors observed that the coatings also had a negligible effect on the average total modulus of the composite structure. Furthermore, the adhesion tape test was also performed after vibration test and again showed no coating loss. This confirmed the robustness of the multilayer stack.

### Example 6—Effect of the Coatings on the Composite Interface

Methods

A number of CFRP substrates were produced to test adhesion strength of the coating-substrate system using a lap-shear strength test. The components were coated as described in Example 1 using alternating layers of poly (para-xylylene) and DLC, and the gluing and lap shear strength measurements were obtained according to DIN EN 2243-1.

All of the samples measured 100 mm×25 mm×10 mm, and were made from quasi-isotropic lay-up. The uncoated samples were cleaned with IPA and prepared for bonding by using the standard grinding process. All samples were glued with space structural adhesive.

In total 19 test specimens were prepared (6 coated not thermal cycled, 4 uncoated not thermal cycled, 6 coated thermal cycled and 3 coated thermal cycled). The single lap shear test was performed according to DIN EN 2243-1 using a Zwick 1747 test bench with adjusted speed.

The thermal tests have been performed in thermal facility using temperature chamber TS-70/600-10/S. More than 60 cycles in total were applied ranging from −50° C. to +80° C.

Lap-shear measurements were performed comparing coated samples against uncoated samples.

Results

The results show that the coated samples exhibit 35% higher average lap shear strength than the uncoated samples. The average lap-shear strength for the coated samples remains 17% higher than that for the uncoated samples even after undergoing more than 60 thermal cycles. Additionally, the standard deviation of the test results was lowered for the coated samples. In particular, for the samples which were not temperature cycled, the standard deviation for the coat samples was 2.43, compared to 5.52 for the uncoated samples. Similarly, for the samples which were temperature cycled, the standard deviation for the coat samples was 2.61, compared to 4.66 for the uncoated samples.

The failure for the uncoated samples was interlaminar inside the layers as a result of the shear stresses, while for the coated one it was close to the cohesive. The inspection (prior/during and after test) of the samples showed that the coating remained intact during all assembly, integration and tests activities. This confirmed wear resistance and robustness of the developed multilayer coating.

The lap-shear results showed that the coating is able to form strong bonds to the CFRP composites as well as to the aerospace glue that is used to prepare the samples. This additional bonding strength, provided by the coating, has the potential to allow stronger structures, thus allowing a lighter design to be achieved. In addition, this allows coating to be present at various levels of manufacturing, raw material or final assembly, without the need to mask or remove the coating.

### Example 7—UV Protection

Materials and Methods

Samples prepared for UV testing are shown in table 4.

TABLE 4
Samples prepared for UV testing

| | | | Dimensions |
|---|---|---|---|
| ID No. | Substrate | Coating | W × L (mm) |
| R7 | Rexolite ® 1422 | Protective coating 2 | 23 × 23 |
| RW1 | Rexolite ® 1422 | None | 23 × 11 |
| R9 | Rexolite ® 1422 | None | 23 × 23 |
| RW3 | Rexolite ® 1422 | Protective coating 2 | 23 × 11 |
| L7 | Eccostock ® LoK | Protective coating 2 | 23 × 23 |
| LW1 | Eccostock ® LoK | None | 23 × 11 |
| L9 | Eccostock ® LoK | None | 23 × 23 |
| LW3 | Eccostock ® LoK | Protective coating 2 | 23 × 11 |

Protective coating 2 comprises alternating layers of parylene and DLC and had a total of four layers. The samples were prepared according to the method described in example 2.

The Newport Oriel Solar Simulator was used, which provides one of the closet spectral matches to solar spectra from artificial source. The xenon arc lamp of the device emits a 5800 K blackbody-like spectrum with occasional line structure. The system design features optical beam homogenization, filtering and collimation. The result is a continuous output with a solar-like spectrum in a uniform collimated beam. Beam collimation simulates the direct terrestrial beam and allows characterisation of radiation induced phenomena.

The UV test parameters are given in table 5.

TABLE 5
UV test parameters

| | |
|---|---|
| UV dose | 1200 ESH |
| AMo Spectral Power | 131 W/m² |
| between 200-415 nm | |
| Total power to be delivered | 157 kW/m² for 12000 ESH |
| between 200-415 nm | |
| Vacuum pressure | <5 · 10⁻⁵ mbar |
| Equilibrium temperature | <80° C. |

The device was calibrated before the test and blank tests were performed to ensure compliance with the required test parameters. The temperature limit was fixed at 80° C. not to affect the material characteristics of the polymers and therefore to respect this requirement, the working distance was adjusted to stabilize the temperature around 60° C. The constants solar acceleration was then determined based on the adjusted working distance with an ORIEL power-meter. The spatial uniformity of the beam has been verified to be less than 10%.

Between 200-415 nm, the average incident power was measured at 660 W/m². Between 200 and 415 nm, the AMO solar spectrum power is 131 W/m². As a consequence, at the beginning of the exposure the solar acceleration was around 5 with these experimental conditions. During the exposure, the UV flux decreased due to the window transmission loss. The decrease of the delivered power was followed with the photodiode. The test was set to stop when the samples received the UV power of 157 kW/m2, corresponding to 1200 ESH. The final UV power received by the samples was recorded as 160.8 kW/m2, corresponding to 1227 ESH.

All of the samples were placed on the vacuum cell without mechanical constraints, as shown in FIG. 10. Two platinum temperatures sensors (Pt sensor 1 and PT sensor 2) were installed with Kapton tape to constantly monitor the temperature.

Results

The full exposure time lasted 282 hours after which the samples received 160.8 kW/m2 which, as mentioned above, corresponds to 1227 ESH. The average solar acceleration factor during the whole test was 4.35.

Visual inspections were undertaken at the beginning of the test and the end of the test. It was noted that a significant change in colour was observed for uncoated samples (R1, R9, L1 and L9). This is typical when polymers age by releasing atoms, particularly hydrogen. This degradation of properties of materials was further analysed by thermo-optical measurements. Meanwhile, no discolouration was observed for any of the coated samples.

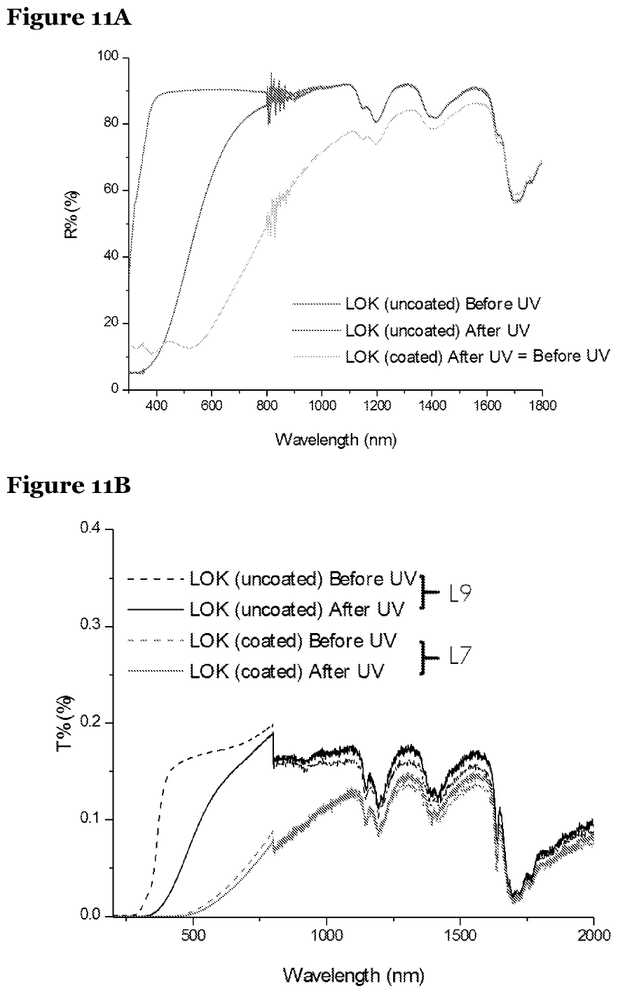

Furthermore, FIG. 11 shows that the reflected and transmission curves observed for the uncoated LOK sample changed significantly after the sample was irradiated. Meanwhile, the reflected and transmission curves for the coated sample were unaffected by the irradiation, supporting the conclusion that the coatings effectively protected the samples from irradiation.

### Example 8—Atomic Oxygen (ATOX) Protection

Materials and Methods

Samples prepared for ATOX testing are shown in table 6.

TABLE 6
Samples prepared for ATOX testing

| ID No. | Substrate | Coating |
|---|---|---|
| R7 | Rexolite ® 1422 | Protective coating 2 |
| U6 | Ultem ® | Protective coating 3 |
| R11 | Rexolite ® 1422 | None |
| DSO4 | CFRP | Protective coating 1 |
| R4 | Rexolite ® 1422 | Protective coating 1 |
| L1 | Eccostock ® LoK | None |
| R5 | Rexolite ® 1422 | Protective coating 2 |
| U5 | Ultem ® | Protective coating 2 |
| DSO9 | CFRP | None |
| R9 | Rexolite ® 1422 | None |
| L6 | Eccostock ® LoK | Protective coating 3 |
| L5 | Eccostock ® LoK | Protective coating 2 |
| U4 | Ultem ® | Protective coating 1 |
| U9 | Ultem ® | None |
| DSO5 | CFRP | Protective coating 2 |
| R6 | Rexolite ® 1422 | Protective coating 3 |
| L5 | Eccostock ® LoK | Protective coating 1 |
| DSO6 | CFRP | Protective coating 3 |
| S5 | CFRP | Protective coating 2 |
| S6 | CFRP | Protective coating 3 |

Protective coating 2 is as described in example 6. Coatings 1 and 3 also had 4 layers. Similar to coating 2, coating 3 was protective. Coating 1 was used for ATOX beam energy monitoring during the tests and it was a more polymer-like coating.

It is noted that R7 and R9 were previously used in the UV protection experiment described in example 6.

All of the samples were 23 mm×23 mm, although S5 and S6 were trimmed to smaller sizes. The Rexolite®, Ultem® and LOK samples were prepared according to the method described in example 2. Meanwhile, the CFRP DSO, CFRP S5 and CFRP S6 samples were prepared according to the method described in example 1.

In order to investigate the difference and potential step height that could be produced due to erosion from ATOX environment, the samples were masked on the corners using Tipp-Ex® and/or conductive aluminium tape (3M 425) which is approved for vacuum processes. In addition, samples holder for ATOX test were manufactured and ensured masking of corners by clamping samples between two metal frames.

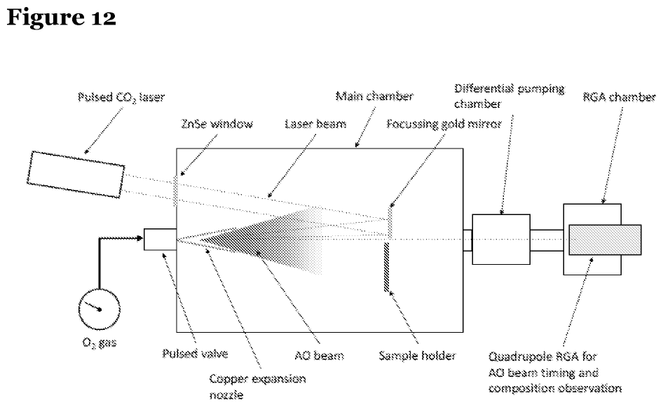

The test was carried out in the European Space Research and Technology Centre (ESTEC) Low Earth Orbit Facility (LEOX) facility that simulates atomic oxygen space conditions. The facility enables production of representative ATOX environment and therefore allows analyse of its effect on the material samples. The ATOX facility produces atomic oxygen at 20000 K from the molecular gas broken down by a CO₂ pulsed laser (ALLMARK APRS model High-performance TEA laser marker). The atoms are accelerated by a nozzle up to 8 km/s. The simulator comprises a vessel composed of three compartments separated by an electro-pneumatic valve and orifice—the main chamber where the atomic oxygen is produced and the samples exposed, the differential pumping chamber and the RGA chamber. The source concept is based on the Laser Pulse Induced Breakdown (LPIB) principle. A schematic of the experimental set-up is shown in FIG. 12.

During the ATOX tests, the environmental conditions were maintained to ensure a temperature of 22 t 3° C. and a relative humidity of 55 t 10%. The required total atomic oxygen fluence was set to 1×10²¹ atoms/cm².

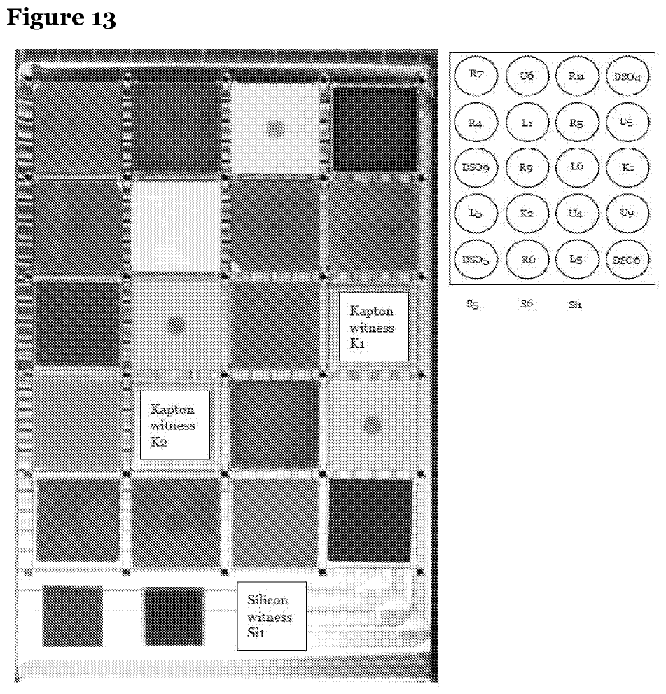

FIG. 13 shows the sample plate assembly which was located in the ESTEC LEOX facility. As shown in the Figure, in positions 12 and 14 two Kapton® HN reference samples (K1 and K2) were provided to control and therefore calculate atomic oxygen fluence using mass loss measurements. These reference samples were exposed together with the test samples. A silicon wafer witness plate (Sit) was also provided to monitor and further analyse any particular contamination.

In total the exposure period covered about 10 working days, where all the samples were exposed to atomic oxygen. The test facility was monitored on a regular basis, and all the critical operating parameters were recorded. The test was performed at vacuum with the pressure 10⁻⁶ mbar.

The sequence of the exposure was as follows:
1^{st} exposure (above 50% of the total required fluence of 1.1×10²¹ atoms/cm²)
Intermediate measurements
2^{nd} exposure (to achieve cumulated total required fluence of 1.1×10²¹ atoms/cm²)

Results

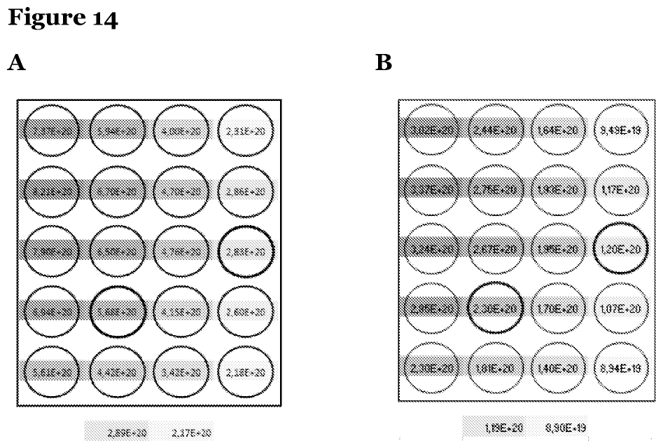

As shown in FIG. 14A, the first exposure run reached a range of effective fluence from 8.21×10²⁰-2.17×10²⁰ across the samples with the average fluence of 4.3×10²⁰ atoms/cm². As shown in FIG. 14B, the second and final exposure run achieved a range of effective fluence from 3.37×10²⁰-8.90×10¹⁹ across the samples, and the average fluence was 1.7×10²⁰ atoms/cm². The accumulated total average fluence on all exposed samples reached 1.1×10²¹ atoms/cm².

A visual inspection conducted after the second run showed discolouring effects on the R11, R9 and U9 uncoated samples. After removing the masking, there was visible erosion with the naked eye for all uncoated materials, comparing the exposed and unexposed areas. The coating was partly removed on the L4 and R4 samples, which were provided with coating type 1. Designed protection coating types 2 and 3 remained untouched.

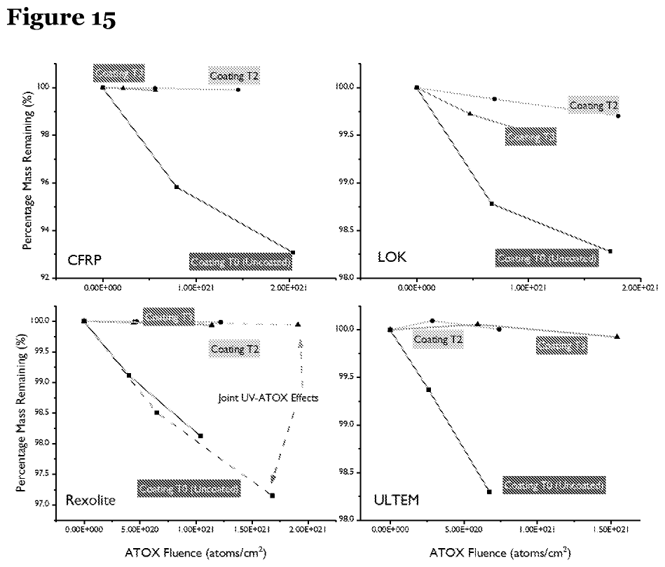

The samples were placed into the same conditioning cabinet before and after the test for at least 20 hours, and weighted on a calibrated Sarotius ME5 micro balance. As shown in FIG. 15, all four uncoated material samples exhibited significant erosion under simulated ATOX conditions. All materials began to be consumed immediately from the beginning of the test without resistance as shown. It is noted that the baseline Rexolite® sample (R9) which has seen combined ATOX & UV effect revealed high susceptibility to these conditions. Coating types 2 and 3 showed resistance to both ATOX and combined ATOX & UV conditions effectively protecting all materials. Using the fluence map, the erosion associated with each sample is adjusted to show the degree of erosion as a function of total effective fluence. This fluence adjusted erosion is compared against the known erosion for Kapton HN, producing a ratio of erosion relative to Kapton HN. This data is consistent with mass loss measurements and is presented in FIG. 6-10.

A confocal laser scanning microscope was used, which allows samples to be scanned sequentially point by point or multiple points at once. The information was assembled into an image obtaining optical sections with high contrast and high resolution in all axes. It allowed advanced topography and materials surfaces analysis of tested samples, especially comparing exposed and unexposed areas. The analysis was consistent with visual inspection and mass loss measurements, and therefore confirmed erosion phenomena on all uncoated samples.

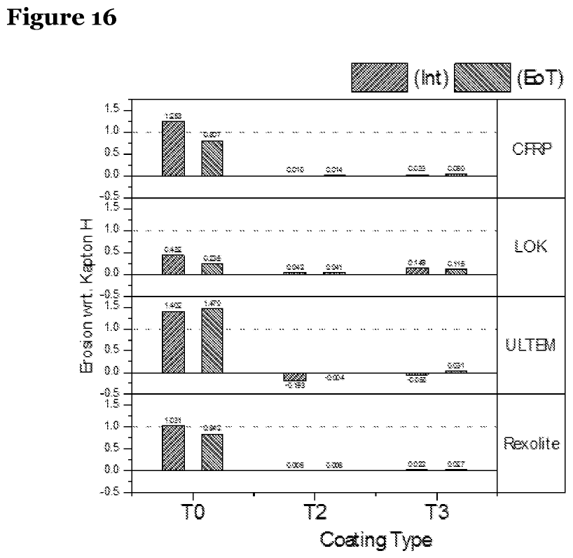

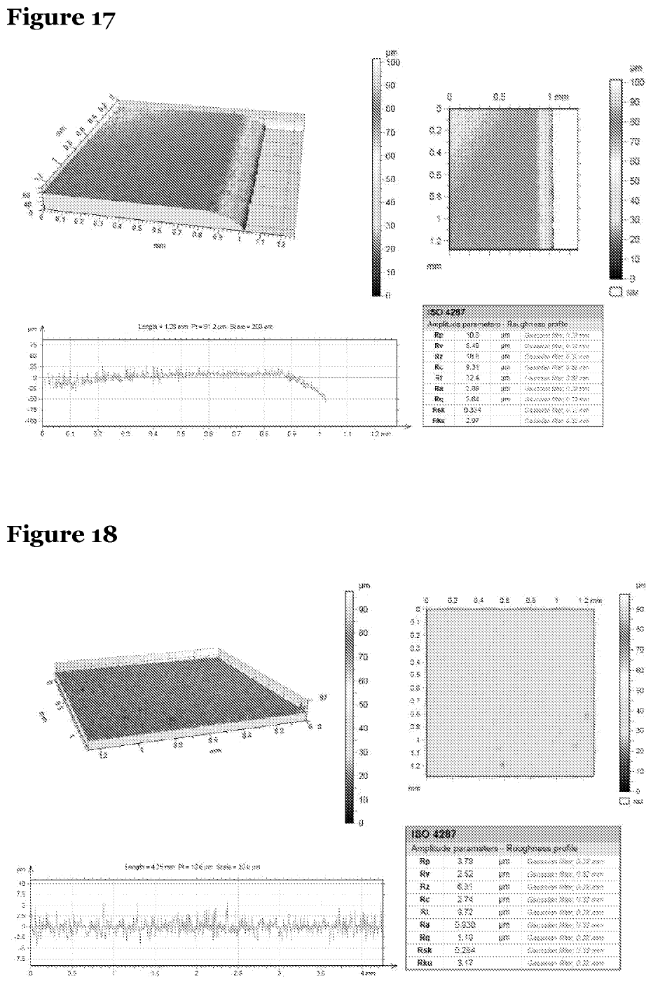

FIG. 17 shows the topography of the R9 sample, which was uncoated and exposed to UV irradiation and ATOX. FIG. 17 shows that as a result of these experiments up to 10% (70-80 μm) of the total thickness of the material has been consumed. Meanwhile, FIG. 16 shows the topography of the R7 sample, which was provided with coating type 2 prior to being exposed to UV irradiation and ATOX. The results show that the coating completely protected the sample. These results are also compatible with measurements of mechanical, optical thickness made before and after the test. The same effects were observed for the other tested materials (CFRP, LOK, ULTEM), with up to 10% materials consumed for uncoated samples whereas samples provided with coating type 2 or 3 were protected with no coating loss. Roughness analysis confirmed the conformal nature of the coatings, as they were used, the smaller roughness of the samples was noted (e.g. uncoated Rexolite Ra-3 m, coated Rexolite coated Ra˜2 μm).

Morphology inspection was performed on all samples before and after UV and ATOX testing at designated measurements points using the same setup with a state-of-the-art Keyence VHX-500 optical microscope. As a result of this analysis, a complete morphology change was observed for all uncoated samples (Rexolite, CFRP, Ultem, LOK) resulting from aging of samples after UV irradiation and/or erosive degradation caused by ATOX. Coatings type 2 and 3 protected all the materials without morphological changes of their structures.

### Example 9—Advantages Associated with Maintaining a Vacuum During Deposition of Multiple Layers

The inventors decided to compare the claimed method to prior art techniques where the vacuum is broken between the deposition of layers. The inventors deposited multiple layers onto substrates using the apparatus described in example 1. In one experiment, the vacuum was maintained without interruption until all of the layers had been deposited. In the second experiment, the vacuum was broken between deposition of each adjacent layers, mimicking a prior art method.

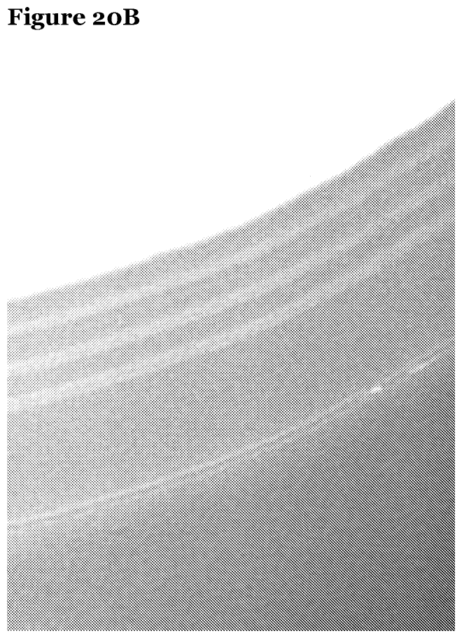

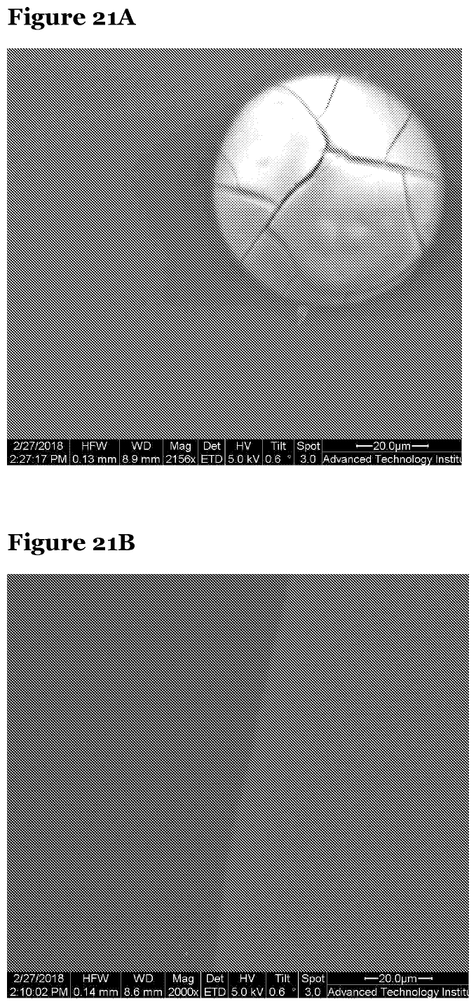

As can be seen in FIGS. 20A and 21A, the sample produced where the vacuum was broken between deposition of adjacent layers exhibits delamination and pinholes. Conversely, as shown in FIGS. 20B and 21B, the sample produced using the claimed method, where the vacuum was maintained without interruption, does not show any delamination or pinholes.

These results support the claim that coating deposited using the claimed method offer improved mechanical integrity and strength.

### Conclusion

The inventors have developed a new method and apparatus for disposing protective layers on a substrate. The coating is deposited at room temperature, and after deposition, it forms an integral part of the composite, so that the “coated component” becomes one composite.

The coating can be applied to any substrate to provide protection or enhanced properties. In particular, the properties that are improved are:

1) Improvement of the mechanical integrity and strength.

2) Improvement of the adhesion of the surface of the coated component to aerospace glue.

3) Transparency to electromagnetic radiation within radio-frequencies.

4) Ability to vary to the optical properties of the coated components, from strong absorption of electromagnetic radiation in the visible and near-infrared (i.e. a “black coating” that absorbs light) to a white-reflective coating that reflects light within these frequencies.

5) Resilience against degradation by erosion from ATOX during spaceflight or low-Earth orbit.

6) Resilience against degradation by erosion from exposure to electromagnetic ultraviolet radiation, in particular visible (VIS) and ultraviolet (UV)

7) Resilience against degradation by erosion from exposure to space radiation such as high-energy proton radiation, high-energy electrons and ions which are permanently trapped around the Earth form the Van Allen belts.

8) Blocking volatile organic compounds that cause the outgassing effect and comes mainly from polymers. The level of contamination of other surfaces is also minimized.

9) Resilience against degradation by corrosion from ground and ATOX environment as well as galvanic, stress and general induced corrosion.

1. A method for depositing a multilayer coating onto a substrate, the method comprising:
supporting the substrate on a platen comprising an electrically conductive material, wherein the platen is disposed in a deposition chamber, is connected to an electrical power supply and is electrically insulated from an electrode;
reducing the pressure in the deposition chamber to less than 10 Torr;
feeding a first feedstock to the substrate;
activating the electrical power supply and thereby creating a plasma that surrounds the substrate and ionises and/or activates particles within the first feedstock;
allowing the ionised and/or activated particles from the first feedstock to deposit on the substrate and polymerise, and thereby form a first layer of a coating on the substrate;
feeding a second feedstock to the substrate such that the plasma ionises and/or activates particles within the second feedstock, wherein the second feedstock is different to the first feedstock;
allowing the ionised and/or activated particles from the second feedstock to deposit on the substrate and polymerise, and thereby form a second layer of the coating on the substrate; and
ensuring the pressure in the deposition chamber does not rise above 700 Torr between feedstocks being fed therein.

2. The method according to claim 1, wherein the pressure in the deposition chamber does not rise above 600 Torr between feedstocks being fed into the deposition chamber.

3. The method according to claim 2, wherein the method comprises forming a further layer of the coating on the substrate by:
feeding a further feedstock to the substrate such that the plasma ionises and/or activates particles within the further feedstock; and
allowing the ionised and/or activated particles from the further feedstock to deposit on the substrate and polymerise, and thereby form a further layer of the coating on the substrate.

4. The method according claim 1, wherein each feedstock comprises:
a feedstock configured to provide a poly(p-xylylene) layer;
a feedstock configured to provide a diamond-like carbon (DLC) layer;
a feedstock configured to provide a layer comprising a metal or metalloid; or
a feedstock configured to provide an inorganic layer.

5. The method according to claim 4, wherein the feedstock configured to provide a poly(p-xylylene) layer comprises a poly(p-xylylene) monomer.

6. The method according to claim 4, wherein the feedstock configured to provide a DLC layer comprises a carbon source.

7. The method according to claim 4, wherein the feedstock configured to provide a metal layer comprises a metal source.

8. The method according to claim 4, wherein the feedstock configured to provide the inorganic layer is conjured to provide a carbide, oxide or nitride, and preferably comprises a carbon, oxygen and/or nitrogen source.

9. The method according to claim 4, wherein the feedstock configured to provide the inorganic layer is conjured to provide a layer comprising a transition metal or p-block metal or metalloid.

10. The method according to claim 1, wherein the method comprises feeding a first feedstock into the deposition chamber when the pressure therein falls below a predetermined pressure of less than 10 Torr.

11. The method according to claim 1, wherein the method comprises monitoring the pressure in the deposition chamber while feeding the first feedstock therein, and activating the electrical power supply after the pressure reaches a predetermined pressure of at least 1 mTorr.

12. The method according to claim 1, wherein before depositing a further layer on the substrate, the method may comprise stopping feeding a feedstock for a previous layer into the deposition chamber and reducing the pressure in the deposition chamber to a predetermined pressure of less than 10 Torr.

13. The method according to claim 1, wherein activating the electrical power supply comprises applying an electrical power to the electrically conductive substrate and/or the platen of between 0.0001 Watts/cm² and 10 Watt/cm².

14. The method according to claim 1, wherein the first feedstock is configured to provide a poly(p-xylylene) layer.

15. The method according to claim 1, wherein the second feedstock is a feedstock configured to provide a DLC layer.

16. The method according to claim 1, wherein a feedstock is a feedstock configured to provide a metal or metalloid containing layer, comprising a metal, a metalloid, a metal suboxide or a metalloid suboxide.

17. The method accordingly to claim 16, wherein the metal or the metal suboxide is titanium (Ti) or titanium suboxide (TiOₓ).

18. The method according to claim 16, wherein subsequent to the feedstock configured to provide a metal or metalloid containing being fed to the substrate and the metal or metalloid containing layer being formed thereon, the method may comprise:
feeding oxygen to the substrate such that the plasma ionises and/or activates the oxygen; and
allowing the ionised and/or activated oxygen to contact the metal or metalloid containing layer, and thereby oxidise the metal or metalloid containing layer.

19. A coated substrate obtained or obtainable utilizing the method of claim 1.

20. An apparatus for providing a multilayer coating onto a substrate, the apparatus comprising:
a deposition chamber;
a vacuum pump configured to reduce the pressure of the deposition chamber to a pressure of less than 10 Torr;
a platen disposed inside the deposition chamber and comprising an electrically conductive material, wherein the platen is electrically connectable to an electrical power supply and configured to support a substrate;
an electrode, wherein the electrode is electrically insulated from the platen; and
feed means configured to sequentially feed a plurality of feedstocks into the deposition chamber without the pressure therein rising above 700 Torr, whereby each feedstock is configured to provide a coating layer on the substrate such that the sequential provision of the plurality of feedstocks provides a multilayer coating.

21. The apparatus according to claim 20, wherein the deposition chamber comprises a conductive material and defines the electrode.

22. The apparatus according to claim 20, wherein the electrode is connected to electrical ground or earth.

23. The apparatus according to claim 20, wherein the electrical power supply is a direct current (DC) power supply or a radio-frequency electrical power supply.
